(19) United States
(12) Patent Application Publication
(10) Pub. No.: US 2022/0397536 A1
(43) Pub. Date: Dec. 15, 2022

(54) SENSORS, IMAGING SYSTEMS, AND METHODS FOR FORMING A SENSOR

(71) Applicant: KLA Corporation, Milpitas, CA (US)

(72) Inventors: Steve Zamek, San Jose, CA (US); David L. Brown, Los Gatos, CA (US); Howard Chern, Morgan Hill, CA (US); Venkatraman Iyer, Sunnyvale, CA (US)

(21) Appl. No.: 17/834,767

(22) Filed: Jun. 7, 2022

Related U.S. Application Data
(60) Provisional application No. 63/210,082, filed on Jun. 14, 2021.

(51) Int. Cl. G01N 21/88; H01L 27/146

(52) U.S. Cl. CPC G01N 21/8806; H01L 27/1464; H01L 27/14683; G01N 2021/8841

(57) ABSTRACT

Sensors, imaging systems, and methods for forming a sensor with a specified depth profile are provided. One sensor includes a substrate and one or more components attached to the substrate. The sensor also includes a sensor die having a thinned backside and energy sensitive elements configured for detecting energy illuminating the thinned backside of the sensor die. The sensor further includes discrete thermally-conductive structures formed between a frontside of the sensor die and the substrate by a flip-chip process thereby bonding the sensor die to the substrate and causing the thinned backside of the sensor die to have a pre-selected shape. At least a portion of the discrete thermally-conductive structures electrically connect the sensor die to the one or more components.

### BACKGROUND OF THE INVENTION

### 1. Field of the Invention

The present invention generally relates to sensors, imaging systems, and methods for forming a sensor. Certain embodiments relate to sensor shape control via sensor assembly.

### 2. Description of the Related Art

The following description and examples are not admitted to be prior art by virtue of their inclusion in this section.

Backside illuminated image sensors can achieve high quantum efficiency (QE) and good modulation transfer function (MTF) and are widely employed for inspection of a variety of semiconductor and other substrates. To enable fast operation, these sensors are closely connected to application-specific integrated circuits (ASICs), which can perform one or several of the following functions: analog-to-digital (A/D) conversion, signal conditioning, digital signal processing, and communication to an external computer.

Such a sensor configuration poses challenges for proper control of the shape of the photo-active area of the sensor. For example, in the case of a backside illuminated sensor, the photo-active area is a thin membrane and can become mechanically unstable. Flip-chip assembly of the sensor die enables fast operation compatible with backside illumination. Upon flip-chip assembly of a sensor onto a ceramic substrate, the sensor may become convex, concave or wrinkled. The effects of flip-chip assembly on sensor shape can pose challenges for optical systems in which highly controlled and simple shape is required. In optical applications, a curved image plane may be preferred with specific curvature. It can be therefore critical to the imaging performance of such systems to be able to control sensor shape during the assembly and to be able to design the assembly to target a specific sensor shape.

Optical system designs typically produce negative curvature, positive curvature, or flat image fields. Image sensors, on the other hand, may be assembled on a ceramic substrate, and the shape of ceramic substrates is difficult to control due to the substrate manufacturing process. Being unable to control the shape of a sensor assembly can decrease the useful field of view, reduce system level optical tolerances, and increase the amount of optical aberration.

The disadvantages of currently used sensor assembly methods therefore include that the ceramic substrate shape cannot be easily controlled, while high-performance optical design may require high sensor planarity or a certain sensor shape. An additional disadvantage of currently-used assembly methods is that relatively poor die co-planarity can make it difficult to properly attach the sensor die, which impacts the thermal performance of the assembly. Another disadvantage of currently used sensor assembly methods is heat dissipation, which is important for high-speed, low-noise operation. A further disadvantage of the currently used sensor assembly methods is that field curvature can make it difficult to achieve a telecentric image space, which can be important in applications of metrology. Furthermore, current assembly methods do not allow good control or repeatability of sensor shape

There are several currently proposed methods for controlling the shape of a backside illuminated thinned sensor die for applications in mobile phones and astronomy. However, in all those applications, wire-bonded sensor dies are used. Wire-bonded sensor dies limit the number of interconnects and the readout speed and are not well-suited for applications of optical inspection described above. Such currently used methods for sensor shape control may also not be suitable for enabling good thermal contact, flip-chip with high density interconnect, or for applications in vacuum.

Accordingly, it would be advantageous to develop systems and methods for sensors, imaging systems, and methods for forming a sensor that do not have one or more of the disadvantages described above.

### SUMMARY OF THE INVENTION

The following description of various embodiments is not to be construed in any way as limiting the subject matter of the appended claims.

One embodiment relates to a sensor that includes a substrate and one or more components attached to the substrate. The sensor also includes a sensor die having a thinned backside and energy responsive elements configured for detecting energy illuminating the thinned backside of the sensor die. The sensor further includes discrete thermally-conductive structures formed between a frontside of the sensor die and the substrate by a flip-chip process, thereby bonding the sensor die to the substrate and causing the thinned backside of the sensor die to have a pre-selected shape. At least a portion of the discrete thermally-conductive structures electrically connect the sensor die to the one or more components. The sensor may be further configured as described herein.

Another embodiment relates to an imaging system that includes an energy source configured for generating energy directed to a specimen by an illumination subsystem. The imaging system also includes a sensor configured for detecting energy from the specimen and generating output responsive to the detected energy. The sensor is further configured as described above. The imaging system may be further configured as described herein.

Another embodiment relates to a method for forming a sensor. The method includes forming discrete thermally-conductive structures on a substrate and altering a shape of the discrete thermally-conductive structures based on a pre-selected shape of a thinned backside of a sensor die. The method also includes bonding a frontside of the sensor die to the substrate via the discrete thermally-conductive structures thereby causing the thinned backside of the sensor die to have the pre-selected shape. At least a portion of the discrete thermally-conductive structures electrically connect the sensor die to one or more components attached to the substrate. The sensor die has energy sensitive elements configured for detecting energy illuminating the thinned backside of the sensor die.

Each of the steps of the method may be further performed as described herein. The method may include any other step(s) of any other method(s) described herein. The method may be performed by any of the systems described herein.

### BRIEF DESCRIPTION OF THE DRAWINGS

Further advantages of the present invention will become apparent to those skilled in the art with the benefit of the following detailed description of the preferred embodiments and upon reference to the accompanying drawings in which:

FIG. 1 is a schematic diagram illustrating a cross-sectional, side view and a plan, bottom view of one embodiment of a sensor assembly;

FIG. 2 is a flow chart illustrating an embodiment of a method for forming a sensor assembly;

FIG. 3 is a flow chart illustrating embodiments of interconnect formation using solder balls and gold studs;

FIG. 4 is a flow chart illustrating an embodiment of a sensor assembly method to comply with a concave or convex solder ball profile;

FIG. 5 is a schematic diagram illustrating cross-sectional views of embodiments of geometries of a free-standing sensor die and the same sensor die in contact with solder bumps;

FIG. 6 is a schematic diagram illustrating a cross-sectional view of an embodiment of a portion of a complete sensor assembly with overlaid arrows indicating the magnitude and direction of heat flux within the sensor assembly;

FIGS. 7a and 7b are schematic diagrams illustrating a side view of embodiments of a camera lens subsystem coupled to sensor embodiments described herein;

FIG. 7c is a contour plot of an example of a curvature of a sensor embodiment as a surface sag;

FIG. 7d is a plot of an example of a geometric root mean square (RMS) spot size across the field of view (FOV) of the embodiments shown in FIGS. 7a and 7b;

FIGS. 8a and 8b are schematic diagrams illustrating a side view of embodiments of a tube lens subsystem coupled to sensor embodiments described herein;

FIG. 8c is a contour plot of an example of a curvature of a sensor embodiment as a surface sag;

FIG. 8d is a plot of an example of a geometric RMS spot size across the FOV of the embodiments shown in FIGS. 8a and 8b;

FIG. 9a is a schematic diagram of a perspective view of one embodiment of a portion of an imaging system that includes more than one sensor configured as described herein;

FIG. 9b is a contour plot of an example of a curvature of the image plane of the portion of the imaging system embodiment shown in FIG. 9a as a surface sag;

FIG. 9c is a contour plot of an example of a curvature of the multiple sensor embodiment shown in FIG. 9a as a surface sag;

FIG. 9d is a contour plot of an example with optimized sensor curvatures of the multiple sensor embodiment shown in FIG. 9a as a surface sag;

FIG. 10 is a schematic diagram illustrating a plan view of embodiments of different grids in the image space that may be projected onto the specimen space;

FIGS. 11 and 11a are schematic diagrams illustrating side views of embodiments of an imaging system configured as described herein; and

FIG. 12 is a block diagram illustrating one embodiment of a non-transitory computer-readable medium storing program instructions for causing a computer system to perform a computer-implemented method described herein.

While the invention is susceptible to various modifications and alternative forms, specific embodiments thereof are shown by way of example in the drawings and are herein described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

In general, the embodiments described herein are sensors, imaging systems, and methods for forming a sensor. More specifically, the embodiments described herein are methods of sensor assembly and shape control for applications such as inspection and metrology. The embodiments provide image sensors including, but not limited to, time delay integration (TDI) sensors for deep ultraviolet (DUV) and extreme ultraviolet (EUV) applications that can operate in partial vacuum or other controlled environment and that are assembled on a variety of ceramic substrates. The embodiments described herein advantageously show how to implement such sensors with controlled sensor shape, while maintaining relatively high-speed, relatively low-noise operation. In addition, the embodiments described herein provide methods for sensor shape control while enabling substantially good thermal contact for the sensor die, flip-chip assembly with substantially high density interconnects, and suitability for applications in a vacuum.

The term “energy sensitive elements” as used herein is defined as sensor elements that are sensitive or responsive to one of the types of energy described herein including light, electrons, other charged particles, and the like. These energy sensitive elements may be formed of different components depending on the type of energy that they will be used to detect. Although many embodiments and examples are described herein using the term “light sensitive elements,” any use of that term is not meant to exclude those embodiments and examples to any other types of energy sensitive elements described herein. In other words, the terms “energy sensitive elements” and “light sensitive elements” are used interchangeably herein for ease, and any instance of the term “light sensitive elements” should be interpreted more broadly as “energy sensitive elements” described herein.

The embodiments also include imaging systems such as inspection systems based on such sensors to thereby achieve superior imaging performance and consequently higher defect sensitivity and throughput compared to currently available inspection systems. Enabling sensor assembly with a controlled curvature as described herein can advantageously increase the optical field of view (FOV) of an imaging system, relax imaging system level optical tolerances, and reduce the amount of optical aberrations in the systems. The embodiments described herein also advantageously enable relatively large sensors and tiled sensor arrays designed for curved image spaces or other non-flat image spaces, which provide higher sensitivity for applications such as inspection with sufficient throughput (and thus lower cost-of-ownership).

As will be seen from the following description of various embodiments, the sensors described herein have a number of additional advantages over currently used sensors. These additional advantages include that although the shape of a ceramic substrate may not be easily controlled, sensor dies can be bonded to such substrates as described herein with substantially high sensor die planarity or a pre-selected, certain sensor die shape thereby rendering the sensors particularly suitable for substantially high performance optical designs. Another advantage of the embodiments described herein is that regardless of a pre-selected sensor die shape, the embodiments described herein enable sufficient contact with the sensor die, which in turn optimizes thermal performance of the assembly thereby enabling relatively high-speed, relatively low-noise operation of the sensor die. A further advantage of the embodiments described herein is that despite any field curvature in an imaging system, the sensor dies can enable a telecentric image space, which is important for metrology applications. These and other advantages described herein are provided by the sensor assembly methods described herein that allow substantially accurate control of the sensor die shape.

As described further herein, the sensor die embodiments have a thinned backside and light sensitive elements configured for detecting energy illuminating the thinned backside of the sensor die. The energy that is detected by the sensor die is directed to the thinned backside and then through the body of the sensor die so that charge can be collected by elements formed on the frontside. The back surface profile defines the location of the image plane of the sensor. As a result, the shape of the sensor die is arguably one of the most important characteristics of the sensor die for reasons including those described further herein.

As used herein, the term “pre-selected shape of the thinned backside of the sensor die” is used interchangeably herein with the terms “sensor shape” and “sensor die shape.” The “pre-selected shape of the thinned backside of the sensor die” is defined herein as a position of the thinned backside of the sensor die with respect to some reference or coordinate system and as a function of position across the sensor die. For example, the “pre-selected shape of the thinned backside of the sensor die” can be defined by the depth or vertical height of the thinned backside of the sensor die as a function of position across the sensor die. This depth or height function may be defined in two dimensions (2D) across the sensor die. Therefore, the “pre-selected shape of the thinned backside of the sensor die” also defines a 2D profile of the sensor backside height or depth. In other words, the “pre-selected shape of the thinned backside of the sensor die” effectively defines the position of the backside of the sensor die in z and as a function of x and y.

As described further herein, the “pre-selected shape of the thinned backside of the sensor die” is enabled by the novel and advantageous sensor assembly methods described herein, which preferably do not alter the thickness or vertical height of the sensor membrane (the light sensitive elements) in any way. The shape of the membrane is constant, and the shape in other dimensions is fixed. In other words, the sensor assembly methods described herein do not alter a shape of the sensor die by altering any characteristics of the light sensitive elements (although some negligible alterations may occur). Instead, the light sensitive elements preferably have the same characteristics prior to sensor assembly and after. In this manner, the changes in the height (or depth) of the backside of the sensor die after sensor assembly will result in a similar change in height (or depth) of the frontside of the sensor die. Conversely, changes in the frontside profile due to attachment to another component will result in similar changes to the backside profile.

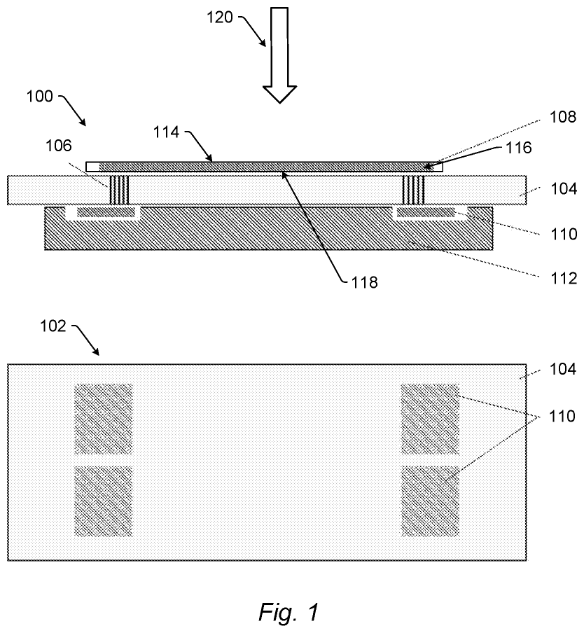

One embodiment of a sensor includes a substrate, one or more components attached to the substrate, and a sensor die bonded to the substrate. In one embodiment, therefore, the image sensor die is co-packaged with other dies assembled onto a common substrate as shown in FIG. 1. FIG. 1 includes side view 100 of a sensor assembly and bottom view 102 of the sensor assembly. As shown in the side view, this embodiment of the sensor assembly includes substrate 104 having electrical interconnects 106 formed therein. At least a portion of electrical interconnects 106 electrically connect sensor die 108 attached to one side of the substrate and one or more components 110 attached to the other side of the substrate. The substrate may also be attached to heat sink 112 on the side of the substrate opposite the sensor die. Bottom view 102 shows the sensor assembly without the heat sink to thereby further show one or more components 110 attached to substrate 104. Although four components are shown in this figure, the sensors may include any number and arrangement of one or more components, which may be configured as described further herein.

As further shown in side view 100, sensor die 108 has backside 114 that is thinned (not shown in FIG. 1) and energy sensitive elements 116 configured for detecting energy 120 (such as light or electrons) illuminating the thinned backside of the sensor die. Energy sensitive elements 116 are shown very generically herein since the embodiments can be applied to many different sensor configurations. In general, energy sensitive elements 116 may include a combination of different elements (not shown), some with different functions. For example, the energy sensitive elements may include elements that actually detect the energy as well as elements that store a signal or charge responsive to the detected energy. In one such example, the energy sensitive elements may be configured such that the energy is converted to electrical charge somewhere near backside 114 of the sensor die (or possibly deeper in the bulk of the sensor die for some cases) and that signal charge is collected and stored in elements on or near frontside 118 of the sensor die.

As described further herein, the embodiments are particularly suitable for situations in which the sensor die is operating within a vacuum such as embodiments in which the energy sensitive elements are configured for detecting DUV light, vacuum or extreme ultraviolet (VUV/EUV) light, an electron beam, and/or x-rays. The embodiments are also suitable for non-vacuum applications such as when the energy sensitive elements are configured for detecting visible or infrared (IR) light.

The sensor die can be configured as a charge coupled device (CCD), a TDI sensor, or a complementary metal-oxide-semiconductor (CMOS) image sensor die. The sensor die can also be made of silicon (Si), indium gallium arsenide (InGaAs), indium antimonide (InSb), cadmium telluride (CdTe), or any other suitable compounds for energy detection across a spectrum including, but not limited to, x-rays, VUV light, DUV light, visible light, and IR light. While some of the embodiments may be described herein with respect to silicon-based sensor dies, the embodiments described herein can be applied to sensors made of any other suitable material(s).

In one embodiment, one or more components 110 are configured for performing one or more functions on output generated by energy sensitive elements 116 responsive to energy detected by the energy sensitive elements. The one or more other components (or other dies) can be analog-to-digital (A/D) chips, digital-to-analog components (DAC), image signal processing dies, application-specific integrated circuits (ASICs), or a combination thereof. The one or more functions performed by the one or more components may include, for example, amplification, A/D conversion, signal conditioning, digital image processing, and communication to an external computer. Therefore, the one or more functions may be as simple as transferring the output of the sensor die to a component external to the sensor assembly or may involve transforming the output from one type to another, altering the sensor output in some manner, etc. The assembly can use a variety of interfaces (not shown in FIG. 1 but shown in other figures described herein) including, but not limited to, pin grid array (PGA), ball grid array (BGA), flexible circuit, and land grid array (LGA). In one embodiment, the substrate is formed of a ceramic material. For example, the substrate is a ceramic preferably based on glass, alumina, aluminum nitride, or other material selected as described further herein.

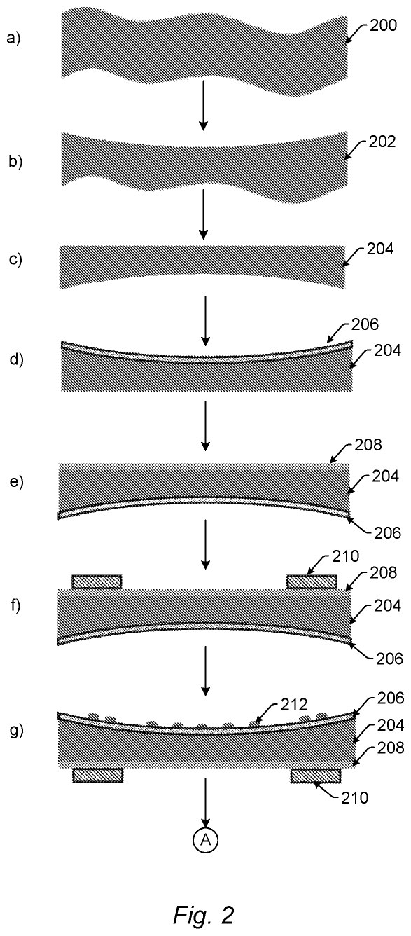

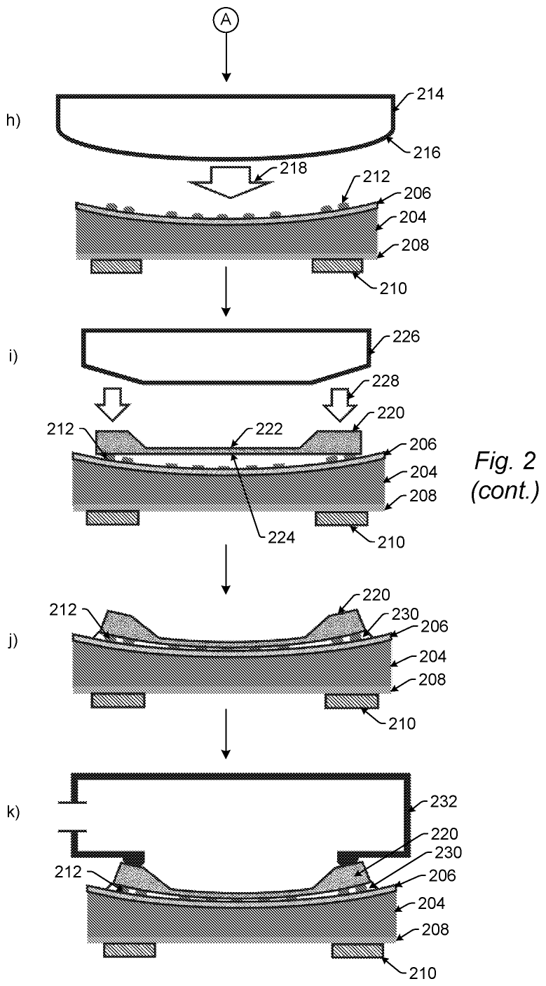

FIG. 2 shows one embodiment of a method for forming a sensor. Although this figure includes steps for making a ceramic substrate and creating a sensor assembly from the substrate, the embodiments described herein may include fewer than all of the steps shown in FIG. 2. For example, rather than starting the method at step a) described further below, the method may start at step g) described below and steps prior to step g) may be performed by another method or system.

As shown in step a), ceramic substrate 200 is made. In this step, the substrate will generally be made thicker than the nominal design to include sacrificial material that is removed in the next step. In step b), the top side of the substrate is polished to the desired shape thereby forming ceramic substrate 202 having a polished top side. This polishing process may expose internal vias (not shown in FIG. 2) formed in the substrate. In step c), the bottom side of the substrate is polished to a flat surface thereby forming ceramic substrate 204 having two polished sides. Although the ceramic substrate is shown in FIG. 2 to be polished to a particular shape on both sides of the substrate, the shape of both sides of the substrate may vary from that shown in FIG. 2 and may be selected as described further herein.

In step d), metal 206 is deposited and patterned on the top side of the substrate. Patterning on a flat surface can be achieved using a standard lithographic method known in the art. Patterning on a concave surface can be achieved using a direct imaging method for patterning such as Direct Imaging, also known in the art. In step e), the same process as in step d) may be implemented on the bottom side of the substrate thereby forming metal 208 on the bottom side of the substrate. Metals 206 and 208 may be formed of any suitable material known in the art and may have any suitable configuration known in the art. In step f), one or more components 210 such as ASIC chips are assembled onto the bottom side of the substrate using any suitable flip-chip process known in the art.

The method includes forming discrete thermally-conductive structures on a substrate. For example, in step g), solder bumping is performed on the top surface to thereby form discrete thermally-conductive structures 212 on the top side of the substrate. The method also includes altering a shape of the discrete thermally-conductive structures based on a pre-selected shape of a thinned backside of a sensor die. For example, in step h), the discrete thermally-conductive structures, e.g., solder balls, may be stamped (coined) by tool 214 with surface 216 polished into the desired shape (a curved shape shown in FIG. 2) lowered in the direction shown by arrow 218 until surface 216 comes into contact with and exerts force upon the discrete thermally-conductive structures.

The method further includes bonding the frontside of the sensor die to the substrate via the discrete thermally-conductive structures thereby causing the thinned backside of the sensor die to have the pre-selected shape. In this manner, the sensor includes discrete thermally-conductive structures formed between the frontside of the sensor die and the substrate by a flip-chip process thereby bonding the sensor die to the substrate and causing the thinned backside of the sensor die to have a pre-selected shape. At least a portion of the discrete thermally-conductive structures electrically connect the sensor die to one or more components 210 attached to substrate 204. For example, not all of the discrete thermally-conductive structures may connect electrically to components or devices. In the region where the light sensitive elements are formed (e.g., the membrane region), the conductive structures may provide mechanical and thermal benefits, but may not have an electrical purpose. The sensor die may be further configured as described herein. For example, as shown in step i), sensor die 220 may have thinned backside 222, frontside 224, and energy sensitive elements (not shown in FIG. 2) configured for detecting energy illuminating the thinned backside of the sensor die.

In step i), the periphery of sensor die 220 is soldered to the substrate using a contact method such as hot-bar or similar. For example, hot-bar 226 may press down on backside 222 of the sensor die in the direction indicated by arrows 228 so that the periphery of the sensor die comes into contact with and is soldered to only the discrete thermally-conductive structures near the periphery of the sensor die. In this manner, after this step, the sensor die may be bonded to only a portion of the discrete thermally-conductive structures, and the sensor die may be bonded to the remaining discrete thermally-conductive structures in a later step.

In one embodiment, the sensor includes an underfill material formed around the discrete thermally-conductive structures and between the frontside of the sensor die and the substrate. In one such embodiment, the underfill material is configured to stabilize the sensor die when the sensor die is subject to a vacuum. For example, one new and advantageous feature of the embodiments described herein is that a curved image sensor packaged onto a ceramic substrate with an underfill allows for vacuum based operation. As shown in step j), underfill resin 230 is applied between sensor die 220 and the substrate to reinforce the solder joints. In this manner, the underfill resin may stabilize the solder joints thereby helping to maintain the shape of the sensor die even in the presence of a vacuum or other pressure applied to the sensor or to which the sensor is otherwise exposed. Such vacuum exposure of the sensor may be needed, for example, if the energy being detected is VUV light, EUV light, electrons, etc. In step k), flow cell 232 is used to pressurize sensor die 220 and establish a contact between the thinner portion of the sensor die and the substrate. Curing of the underfill can be applied at this step as well.

As shown in steps j and k), the backside of the sensor die may have a curved shape after the sensor die has been bonded to all of the discrete thermally-conductive structures, which have been stamped or coined to have, in combination, the pre-selected shape. One new and advantageous feature of the embodiments described herein is therefore that a back-thinned curved image sensor can be assembled via a flip-chip process, which allows both backside illumination for DUV, VUV, etc., and substantially high speed operation.

The steps shown in FIG. 2 may be modified in one or more ways described further herein. For example, in step b), the front side of the ceramic may be polished to a flat surface instead of a curved surface as may be the case when an application needs a substantially flat sensor die. In that case, the method shown in FIG. 2 may be applied equally well, but the ceramic manufacturing process and the assembly process may be significantly simplified.

Each of the steps of the method may be further performed as described herein. The method may also include any other step(s) that can be performed by the sensor, imaging system, computer subsystem, component(s), etc., described herein. The sensor formed by the method described above and an imaging system in which it is included may be configured according to any of the embodiments described herein. The method may be performed by any of the system embodiments described herein.

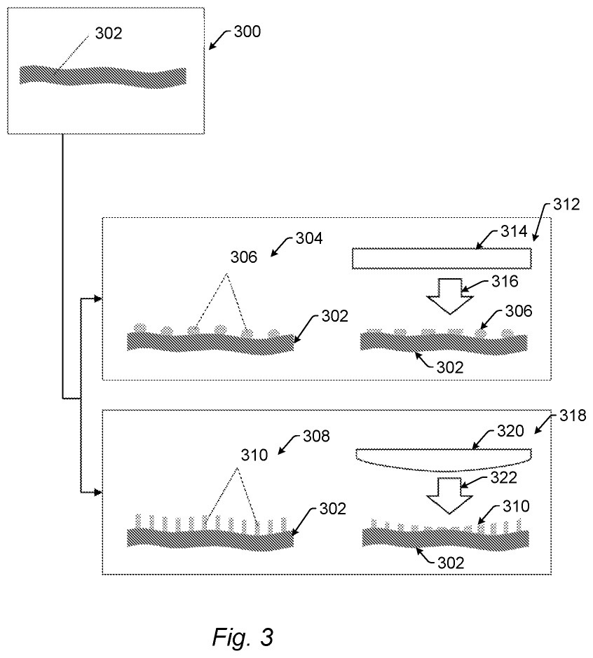

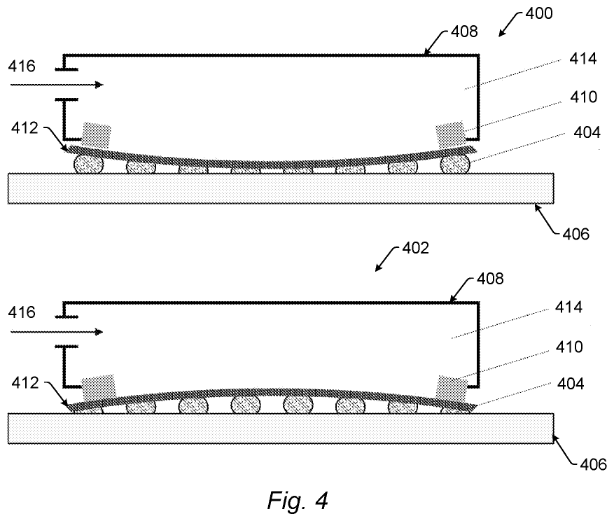

The general idea of assembly of an integrated circuit (IC) onto a substrate with coined solder bumps is described in U.S. Patent Application Publication No. 2012/0309187 by Sri-Jayantha et al. published Dec. 6, 2012, which is incorporated by reference as if fully set forth herein. However, a challenge of implementing such a method for an image sensor stems from the fact that mechanical contacting of the sensor die surface is undesired as it may damage the pixel array and result in relatively low assembly yield. FIG. 3 shows one embodiment of how the substrate may be formed, and FIG. 4 shows one embodiment of a process flow of sensor assembly.

In step 300 of FIG. 3, ceramic substrate 302 is made using a co-firing process, which may be any suitable such process known in the art. The substrate will exhibit camber and non-flatness due to the differential shrinkages of the ceramic layers and the conductive ink (not shown) within the ceramic. In the next step, an interface material is applied. Preferably, the interface material is soft enough to enable forming by stamping or coining. Examples of such interface materials include, but are not limited to, solder bumps and gold studs. For example, in step 304, solder bumps 306 may be formed on ceramic substrate 302. In the case of gold studs, in step 308, gold studs 310 may be formed on ceramic substrate 302.

The interface material will then be coined using a forming tool. For example, in step 312, solder bumps 306 may be stamped or coined by tool 314 that is moved in a direction shown by arrow 316 to bring the tool into contact with and exert force upon the solder bumps. In a similar manner, in step 318, gold studs 310 may be stamped or coined by tool 320 that is moved in a direction shown by arrow 322 to bring the tool into contact with and exert force upon the gold studs.

One new and advantageous feature of the embodiments described herein is that they enable substantially precise control of back-thinned image sensor shape using stamping/coining of under-membrane bumps, which allows tailoring the sensor shape to a particular field curvature. For example, in one embodiment, prior to bonding the sensor die to the substrate in the flip-chip process, the discrete thermally-conductive structures are formed on the substrate and a shape of one or more of the discrete thermally-conductive structures is modified so that the discrete thermally-conductive structures in combination have a shape that is substantially the same as the pre-selected shape. In another embodiment, the pre-selected shape is determined prior to the flip-chip process, and a shape of one or more of the discrete thermally-conductive structures formed on the substrate prior to bonding the sensor die to the substrate in the flip-chip process is altered based on the pre-selected shape. As shown in FIG. 3, the shape of the surface of the tool that is used to stamp or coin the discrete thermally-conductive structures may be different for different embodiments and may vary depending on the pre-selected shape. In particular, the shape of the surface of the tool that contacts the solder bumps or the gold studs may be substantially the same as the pre-selected shape so that the pre-selected shape is transferred to the solder bumps or the gold studs and then the sensor die when it is bonded to the solder bumps or gold studs.

In one embodiment, a surface of the substrate on which the discrete thermally-conductive structures are formed has a shape different than the pre-selected shape. For example, in the embodiment shown in FIG. 3, the shape of the solder bumps is altered by the stamping or coining performed with a tool having a substantially flat surface so that the solder bumps in combination have a substantially flat surface after stamping or coining. Such stamping or coining of the solder bumps would be appropriate for instances in which the pre-selected shape is a substantially flat shape. As can be seen in FIG. 3, the stamped or coined solder bumps can also have a substantially flat surface across the combination of the solder bumps despite the non-flatness or camber of the ceramic substrate. In this manner, when the frontside of the sensor die is bonded to the stamped or coined solder bumps, the sensor assembly may have a substantially flat profile despite the non-flatness or camber of the ceramic substrate.

In contrast, as shown in FIG. 3, the shape of the gold studs is altered by the stamping or coining performed with a tool having a curved surface so that the gold studs in combination have a curved surface after stamping or coining. Such stamping or coining of the gold studs would be appropriate for instances in which the pre-selected shape is a curved shape. As can be seen in FIG. 3, the stamped or coined gold studs can also have a curved surface across the combination of the gold studs that is different than the shape of the ceramic substrate. In this manner, when the frontside of the sensor die is bonded to the stamped or coined gold studs, the sensor assembly may have a curved shape despite the non-flatness or camber of the ceramic substrate and despite the difference between the pre-selected curved shape for the backside of the sensor die and the shape of the surface of the ceramic substrate. As such, altering the shape of the discrete thermally-conductive structures as described herein reduces the constraints on the shape of the ceramic substrate.

FIG. 4 further shows how the solder can be coined to either a concave (top), convex (bottom), or any other surface of arbitrary shape. In other words, embodiment 400 shows a method of sensor assembly to comply with a concave solder ball profile, and embodiment 402 shows a method of sensor assembly to comply with a convex solder ball profile. In both instances, solder balls 404 may be formed on substrate 406. As shown in both embodiments, the substrate has a shape that is neither concave nor convex since it does not have to have the same shape as that selected for the sensor die. The solder balls and the substrate may be formed as described herein and may be configured as described further herein. Although FIG. 4 is shown and described with respect to solder balls, other discrete thermally-conductive structures described herein may be altered in shape as shown in this figure.

The forming tool and the shape of the discrete thermally-conductive structures will determine the exact shape of the sensor die that will consequently be assembled onto the substrate. When the sensor die is placed onto the shaped discrete thermally-conductive structures, the discrete thermally-conductive structures are heated to reflow the discrete thermally-conductive structures and establish a permanent connection between the sensor die and the substrate. While heated, the sensor die has to be pressed against the substrate, which can be performed by a variety of means such as pressing with a hot bar on the periphery of the sensor die or by applying a gas pressure through a dedicated fixture. In the embodiments of FIG. 4, partial enclosure 408 in combination with seal-ring 410, which is in contact with sensor die 412, forms flow chamber 414. Application of pressure through the flow chamber, e.g., via gas flow 416 that controls the pressure within the flow chamber and onto the sensor die, will force the sensor die to comply with the shape of the coined discrete thermally-conductive structures.

The embodiments described further herein show practical examples where the sensor die is designed to have particular shapes. As described further herein, in one embodiment, the pre-selected shape is a curved shape. In another embodiment, the pre-selected shape is defined by a higher order polynomial. For example, it is worth highlighting the example where the sensor shape can be described by high-order polynomials, enabling greater flexibility in an optical system design.

In some embodiments, a surface of the substrate on which the discrete thermally-conductive structures are formed has a shape determined based on the pre-selected shape. For example, if the ceramic substrate substantially deviates from the desired shape and the solder balls cannot bridge the gap between the desired sensor die shape and the shape of the ceramic, the ceramic substrate can be polished to the desired shape and the top metal pattern that defines the solder pads can be patterned on the surface. This may be performed as described and shown in steps b) and d) described above with reference to FIG. 2.

In some embodiments, the substrate is formed of a material selected based on a coefficient of thermal expansion (CTE) for the material determined from a size of the sensor die and the pre-selected shape. In another embodiment, the discrete thermally-conductive structures are formed of a material selected based on a reflow temperature for the material determined from a size of the sensor die and the pre-selected shape. Methods for selecting the substrate and solder materials are now described that can help ensure that the assembled sensor is capable of meeting performance requirements.

Since the reflow of solder happens at an elevated temperature, both the sensor die and the ceramic substrate shrink when cooling to room temperature or the operating temperature. This change in temperature poses several challenges to both achieve the desired die shape and also assure solder joint reliability due to stress. The conditions for substantially stress-free solder joints can be determined based on geometric considerations using a simple 1D model.

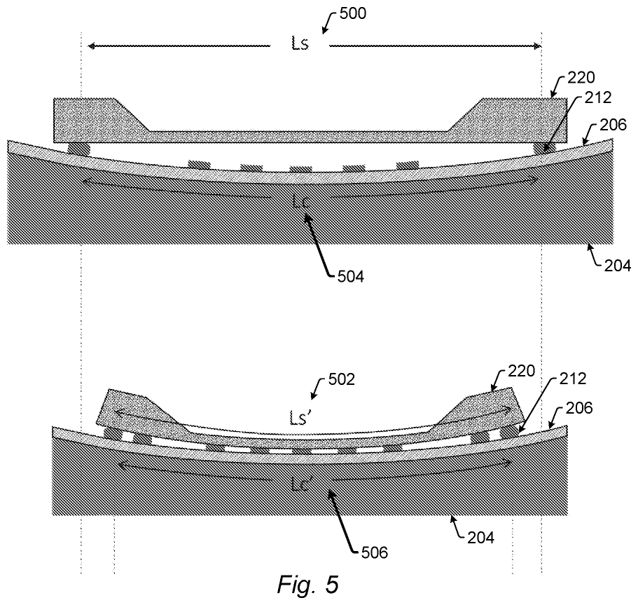

An embodiment showing an initially flat sensor die and fully compliant final shape are shown in FIG. 5. During the solder reflow in step i) of FIG. 2 at relatively high temperature, the sensor die presumably has an initial length Ls as shown by dimension 500 in FIG. 5. After cooling down to the target temperature, and subsequent steps j) and k) of FIG. 2, the sensor die will comply with the coined bump profile assuming the final length Ls' as shown by dimension 502 in FIG. 5. The substrate will also undergo shrinkage due to the temperature differences, so that the length between the outer bump pads will shrink from Lc as shown by dimension 504 to Lc′ as shown by dimension 506. The mismatch between the differential shrinkage will result in residual stress in the solder joints which will be worst for the outer bumps close to the die periphery.

In this example, the stress in the outer solder joints will be minimized when the differences (Lc′−Ls′) can be minimized. Stress-free solder joints are achieved when Lc′−Ls′=0. The requirements to meet this condition can be modified from simple geometric considerations. For the example illustrated in 1D and assuming no bending of the ceramic substrate, we obtain

$$( {α}_{c} - {α}_{s} ) \cdot Δ T \approx \frac{1}{6} {( \frac{{{L}^{′}}_{S}}{R} )}^{2}$$

where R is the target radius of curvature of the die, α_{C} and α_{S} are the coefficients of thermal expansion (CTE) for the ceramic and the silicon die, and ΔT is the temperature difference from the reflow in step j) to step k) of FIG. 2. Parameters L_{S}′ and R are set by the application requirements. Parameters α_{C} and ΔT can be chosen by selecting the proper ceramic material and the solder. Ceramic materials with CTE larger than that of the silicon die are commercially available. ΔT is determined by the solder choice. Solders with a variety of reflow temperatures are also commercially available.

While the example is a simplified case with several approximations, it illustrates the method of selecting key process conditions to minimize solder stress in the proposed assembly. For an actual 2D geometry, the conditions may be obtained using numerical modeling. In the simple case of a flat sensor die (R is infinity), optimum conditions are obtained when there is a close CTE match between sensor die and ceramic substrate. Ceramic IC substrates with CTE closely matching silicon are also commercially available from multiple suppliers. These materials span a range of CTE and include both oxide and non-oxide ceramics. Non-oxide ceramics include aluminum nitride (CTE ˜4.4-4.7 ppm/° C.), silicon carbide (CTE ˜3.7-3.9 ppm/° C.), and silicon nitride (CTE ˜2.8-3.5 ppm/° C.). The ranges indicate a variety of compositions with different CTE for each type. Oxide-based ceramics such as those commercially available from Kyocera Corporation, Kyoto, Japan, include materials with a CTE ranging from 3.4 to 12.3 ppm/° C. For a silicon die, the CTE is 2.6 ppm/° C. For a given die size and curvature, the material with an optimum CTE can be chosen via any suitable numerical modeling known in the art.

To further minimize the mismatch, solder with the desired reflow temperature is used. A variety of solder materials are commercially available spanning the entire temperature range from ˜60° C. to over 220° C. These include indium-bismuth-tin (In—Bi—Sn), indium-bismuth (In—Bi), indium-tin (In—Sn), tin-silver-copper (SACx), and other alloys, commercially available from multiple suppliers. It becomes clear how choosing proper solder and ceramic materials enables to select parameters α_{C} and ΔT and therefore approach the condition of substantially stress-free solder joints. The discrete thermally-conductive structures made of solder may also contain multiple materials with distinguishable differences in melting points. One of the materials may advantageously be a solder with a higher melting point that would more easily maintain its desired shape, and another of the materials may be a solder with a lower melting point that can make electrical connection to components or devices at a much lower temperature. Such combinations of materials may be selected in any suitable manner from any suitable commercially available solder materials.

For substantially fast operation, it is necessary to bring a relatively large number of interconnect signals from the sensor die to the one or more components, e.g., ASICs. Driving the many circuits requires transistors. An example of such an implementation is provided in U.S. Pat. No. 10,764,527 to Chuang et al. issued Sep. 1, 2020, which is incorporated by reference as if fully set forth herein. The sensors described herein may be further configured as described in this patent. To enable substantially fast operation and a relatively large number of signals, the packaging technology must offer a relatively high density of routing in the ceramic substrate and relatively low channel parasitic capacitance. Both are enabled simultaneously by flip-chip assembly of the sensor die on a low-temperature cofired ceramic (LTCC). Interconnects at 150 um pitch and below are available in such technology. Such interconnects can enable in excess of 10 Gigasamples/second (GS/s) of data to be transferred across the ceramic substrate to the ASICs.

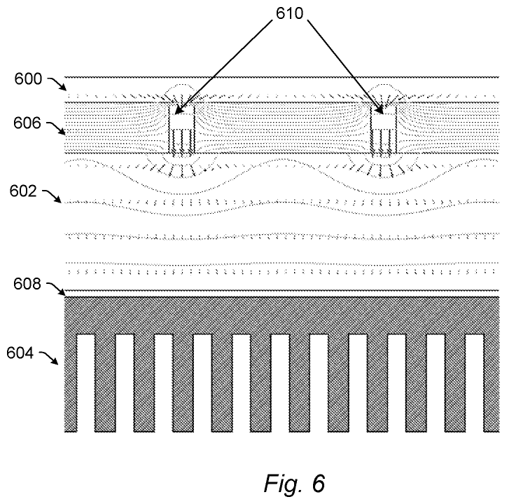

FIG. 6 shows a cross-section of a complete sensor assembly including sensor die 600, ceramic substrate 602, heatsink 604, interface materials including resin 606 and interface material 608, and bumps 610 that bond the sensor die to the substrate. The embodiment shown in FIG. 6 may include other elements that are not shown in this figure but are described further herein. For example, the portion of the complete sensor assembly shown in FIG. 6 corresponds to the central portion of the sensor assembly shown in FIG. 1 that is between the electrical interconnects and the one or more components, e.g., ASICs. Only a portion of the overall sensor assembly is shown in FIG. 6 so that additional detail related to the thermal transfer within the sensor assembly can be more clearly shown.

Overlaid arrows in this figure indicate the magnitude and direction of heat flux within the sensor assembly. The method of assembly embodiments described herein have thermal advantages for the sensor assembly. For example, bumps 610 supporting the sensor die not only define the sensor die shape, but also serve as an efficient thermal conduit of the heat generated by the image sensor die. The gap between the sensor die and the ceramic substrate may be filled with a resin that solidifies and reinforces the solder connections for reliability. All resins developed in the electronics industry for that purpose exhibit relatively low thermal conductivity, typically below 1 W/mK (Watt per meter-Kelvin). The thermal conductivity of solder bumps or gold pillars is substantially higher, meaning most of the heat flux will be conducted by these discrete thermally-conductive structures. FIG. 6 shows the result of thermal modeling of such interfaces including the resin and the solder bumps. The thicknesses shown in the cross-section of the assembly are not to scale for clarity. The overlaid arrows show the direction of heat flow and the length of the arrows is proportional to the magnitude of the heat flux. As shown in this figure, the thermal conductance from the sensor die to the ceramic substrate will be determined primarily by the bumps rather than by the resin.

In one embodiment, the sensor includes thermally and electrically conductive vias formed in the substrate with at least a subset configured for connecting the at least the portion of the discrete thermally-conductive structures to the one or more components thereby connecting the sensor die to the one or more components. For example, to further improve the thermal performance of the sensor assembly, ceramic substrate 602 may include an array of thermally and electrically conductive vias (not shown in FIG. 6). In another embodiment, the underfill material includes a resin containing dispersed particles formed of a dielectric material with high thermal conductivity. For example, underfill resin 606 may preferably include dispersed particles (not shown). Such particles are preferably made with dielectric material with high thermal conductivity such as aluminum nitride, sapphire, or diamond. In general, a “high thermal conductivity” as that term is used herein is defined as a thermal conductivity from 30 W/mK to 2000 W/mK.

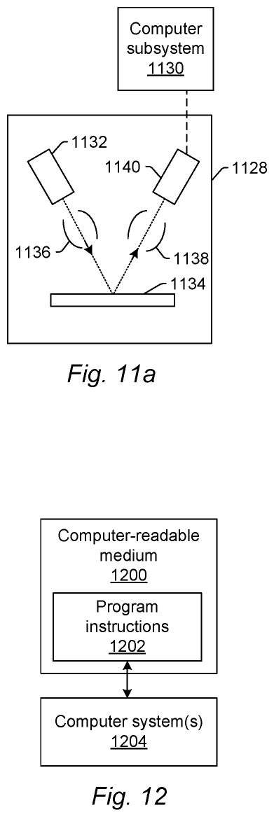

Another embodiment relates to an imaging system. In general, the imaging system includes an energy source (e.g., a light source, an electron beam source, etc.) configured for generating energy directed to a specimen by an illumination subsystem. Such an energy source and illumination subsystem may be configured as described further herein and shown in FIGS. 11 and 11a. In some embodiments, the specimen is a wafer. The wafer may include any wafer known in the semiconductor arts. Although some embodiments may be described herein with respect to a wafer or wafers, the embodiments are not limited in the specimens for which they can be used. For example, the embodiments described herein may be used for specimens such as reticles, flat panels, personal computer (PC) boards, and other semiconductor specimens.

The system also includes a sensor configured for detecting energy from the specimen and for generating output responsive to the detected energy. The sensor is configured as described further herein. The energy that is detected by the sensor may include any energy described herein such as electrons, charged particles, x-rays, VUV light, EUV light, DUV light, visible light, and IR light. As described further herein, the type of energy that is detected by the sensor may also include specularly reflected light, scattered light, or both, depending on the configuration of the system. The output that is generated by the sensor may include any suitable output such as image data, image signals, non-image data, non-image signals, etc., or some combination thereof. The sensor and one or more elements of the imaging system that are coupled to it may be further configured as described herein.

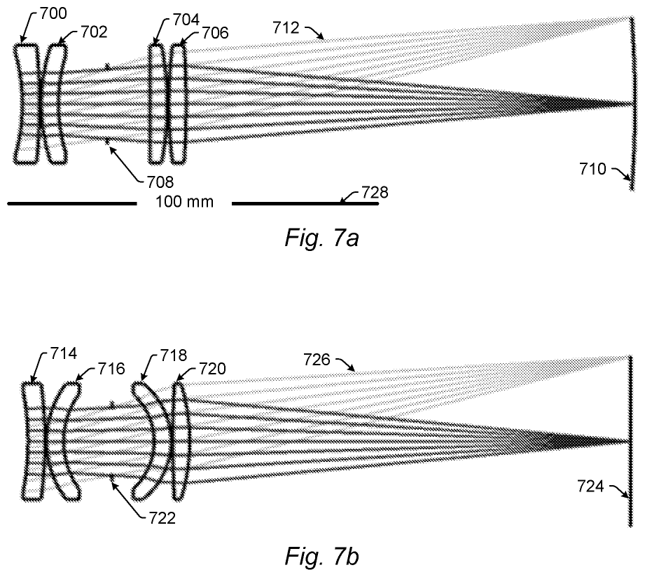

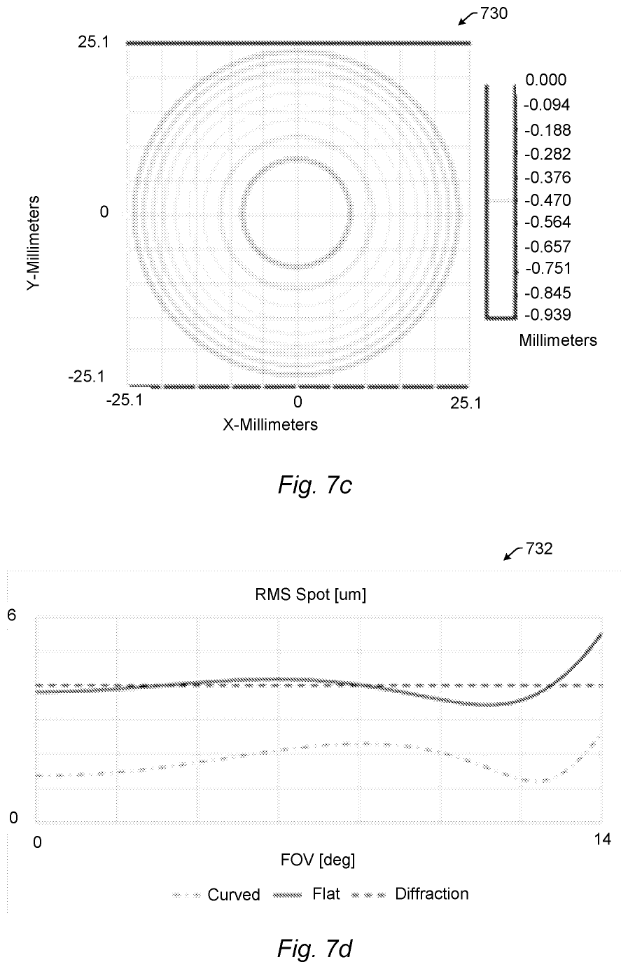

In one embodiment, the imaging system includes a camera lens subsystem configured to direct the energy from the specimen to the sensor. For example, an image sensor having a pre-selected curved shape may be used in a camera lens system as shown in FIG. 7a, and an image sensor having a pre-selected flat shape may be used in a camera lens system as shown in FIG. 7b. In FIG. 7a, the camera lens subsystem includes four refractive lenses 700, 702, 704, and 706 and aperture stop 708 that in combination focus light 712 to image sensor 710 having a curved shape. In a similar manner, in FIG. 7b, the camera lens subsystem includes four refractive lenses 714, 716, 718, and 720 and aperture stop 722 that in combination focus light 726 to image sensor 724 having a substantially flat shape. FIGS. 7a and 7b show the two designs optimized for the curved vs. flat image sensor. In the former case, sensor curvature is optimized as well. By way of example, the following system specifications can be chosen for such a system: FOV of ±14 deg, aperture stop diameter of 20 mm, sensor format 50 mm diagonal, image space F-number (f/#)=5.5, and effective focal lens (EFL) 728 of 100 mm. Such parameters represent an example of typical application requirements for a narrow-band design that can be adopted to the wavelength of interest in DUV, visible, or IR spectrum.

Although the camera lens subsystems are shown in FIGS. 7a and 7b as including four refractive lenses, the camera lens subsystems may include a different number of refractive lenses. In addition, the camera lens subsystems shown in FIGS. 7a and 7b may be modified to include one or more reflective lens elements (not shown) instead of or in combination with one or more refractive lens elements. Furthermore, as can be seen in FIGS. 7a and 7b, the shapes of the refractive lens elements, which are only shown generally in these figures, may be modified depending on the shape of the image sensor. In particular, as can be seen from FIGS. 7a and 7b, refractive lenses 704 and 718 have substantially different shapes, and even refractive lenses 706 and 720 have at least somewhat different shapes. The shapes of all of the refractive elements shown in FIGS. 7a and 7b are not intended to be limiting or indicative of any actual refractive lens or reflective mirror properties that may be used with the image sensors. Instead, as would be clear to one of ordinary skill in the art, the refractive lenses and any other elements included in the camera lens subsystem may be optimized depending on the configuration of the sensor as well as the overall configuration of the imaging system in addition to the application for which the sensor will be used (e.g., scattered light vs. specular light, inspection vs. metrology, DUV light vs. VUV light, etc.).

FIG. 7c shows the image sensor die's curvature as surface sag 730, which is the result of the optimization. Such surface profile can be achieved using the method described above. As to the exact values shown in this plot and the exact curvature they correspond to, they are immaterial to the understanding of the present embodiments. These values and the surface sag may be determined and optimized in any suitable manner known in the art based on the considerations described further herein, and this plot is included here to graphically illustrate how the characteristics of the sensor die shape can be determined and optimized. FIG. 7d shows the geometric root mean square (RMS) spot size across the FOV. RMS spot size is the measurement of the amount of aberration introduced by the system. The two plots correspond to the two cases of the flat sensor die (solid line) vs. the curved one (comprised of both dashes and dots). The other line shown in this figure (comprised of only dashes) corresponds to what would be the diffraction limited imaging in the imaging system. As can be clearly seen from this plot, the curved sensor die enables significantly reduced image blur than the flat-shaped sensor die. In an inspection system, the reduced blur translates to a higher level of defect detection, i.e., higher inspection sensitivity. Again, as to the exact values shown in this FIG. 7d plot and the exact aberrations they correspond to, they are immaterial to the understanding of the present embodiments. This plot is merely included here to graphically illustrate how different sensor die shapes can affect aberrations in the imaging system.

The aperture stop of a design based on a curved image sensor die can also be increased from that based on a flat sensor die. In the example provided in FIG. 7a, the aperture stop can be increased up to 26 mm diameter while matching the aberrations of the initial design. That means that the light-collecting power of the camera lens subsystem would increase by a factor of (26/20)² or by ˜70%. This increased light collecting ability improves the detected optical signal thereby resulting in a higher level of defect detection. Such a lens may be optimized for the application of wafer, panel, or IC substrate imaging for the purpose of film metrology for visual inspection and review of relatively large defects.

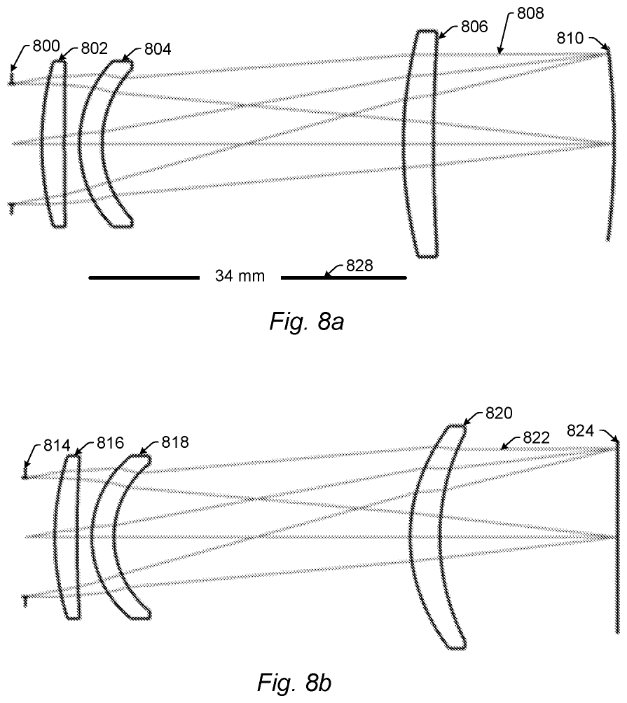

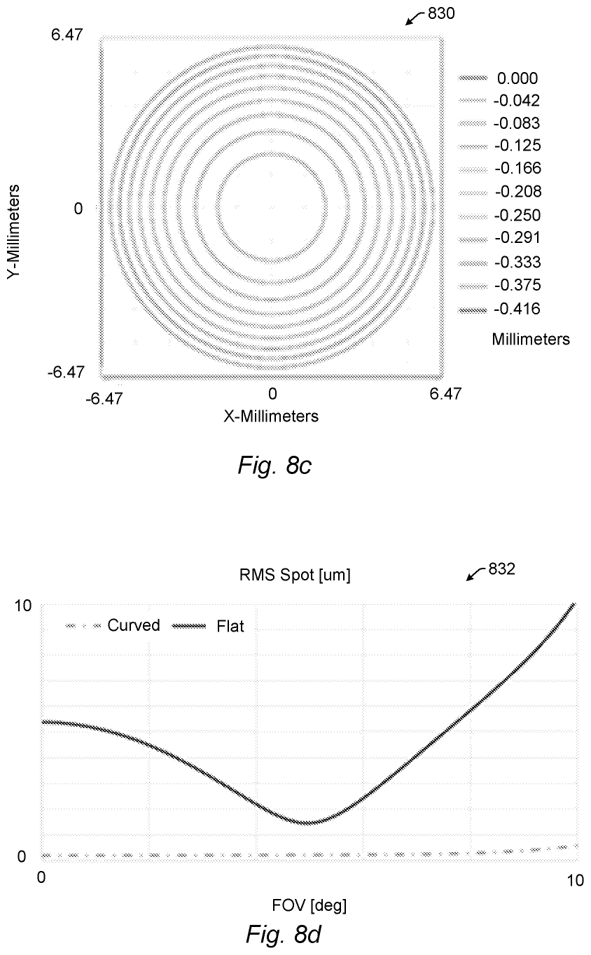

In another embodiment, the system includes a tube lens subsystem configured to direct the energy from the specimen to the sensor. Such a configuration may be used for a tube lens in a DUV camera used with a microscope. In this embodiment, an image sensor having a pre-selected shape is used with a tube lens subsystem, as shown in FIGS. 8a and 8b. For example, an image sensor die having a pre-selected curved shape may be used in a tube lens subsystem as shown in FIG. 8a, and an image sensor die having a pre-selected flat shape may be used in a tube lens subsystem as shown in FIG. 8b. In FIG. 8a, light may enter the tube lens subsystem via aperture 800, and the tube lens subsystem includes three refractive lenses 802, 804, and 806 that in combination focus light 808 to image sensor die 810 having a curved shape. In a similar manner, in FIG. 8b, light may enter this tube lens subsystem embodiment via aperture 814, and the tube lens subsystem includes three refractive lenses 816, 818, and 820 that in combination focus light 822 to image sensor die 824 having a substantially flat shape. By way of example, the following system specifications were chosen: FOV=±10 deg, aperture stop diameter=8 mm, sensor format of 12 mm diagonal, image space F-number (f/#) 4.2, EFL 828 of 34 mm, and total lens track of <40 mm.

Although the tube lens subsystems are shown in FIGS. 8a and 8b as including three refractive lenses, the tube lens subsystems may include a different number of lenses. In addition, the tube lens subsystems shown in FIGS. 8a and 8b may be modified to include one or more reflective and/or diffractive lens elements (not shown) instead of or in combination with one or more refractive elements. Furthermore, as can be seen in FIGS. 8a and 8b, the properties of the elements, which are only shown generally in these figures, may be modified depending on the shape of the image sensor die. In particular, as can be seen from FIGS. 8a and 8b, refractive lenses 806 and 820 have different shapes. The design examples shown in FIGS. 8a and 8b are not intended to be limiting or indicative of any design or lens material required for image sensors. Instead, as would be clear to one of ordinary skill in the art, the elements included in the tube lens subsystem may be optimized depending on the configuration of the sensor as well as the overall configuration of the imaging system in addition to the application for which the sensor will be used (e.g., scattered light vs. specular light, inspection vs. metrology, DUV light vs. VUV light, etc.).

A tube lens subsystem that includes three elements was optimized for two cases, one where sensor die curvature is allowed as shown in FIG. 8a and one where the sensor die was constrained to be flat as shown in FIG. 8b. The results of these optimizations are shown in FIGS. 8c and 8d, respectively. FIG. 8c shows contour plot 830 of a sensor surface sag in units of mm, which is the result of optimization. This corresponds to a radius of curvature of about 50 mm. A sensor die with such a shape can again be obtained using the method embodiments described herein. Use of only three optical elements with two conic surfaces (L1-L and L3-L) leads to a design that is diffraction limited over the entire FOV.

Aberrations of such designs are about 10 times lower compared with an equivalent design based on a planar image sensor die, as shown in plot 832 of RMS spot size in FIG. 8d. Most importantly, the design achieves more than 2× reduction in distortion and substantially low chief ray angle for more uniform sensor responsivity across the FOV. The geometric aberrations are in the sub-micron range, which is substantially below the pixel size for any practical image sensor. Lower aberrations are particularly advantageous for optical inspection applications of patterned wafers, panels, or IC substrates. The example shows how the use of a curved image sensor die enables a simple tube lens design for those applications. In particular, the use of sensor curvature can reduce the number of reflective elements required and increase the practical field size possible for systems that use EUV illumination. These systems are highly constrained and require costly elements and fabrication methods.

As to the exact values shown in the plot of FIG. 8c and the exact curvature they correspond to, they are immaterial to the understanding of the present embodiments. These values and the surface sag may be determined and optimized in any suitable manner known in the art based on the considerations described further herein, and this plot is included here to graphically illustrate how the characteristics of the sensor die shape can be determined and optimized. FIG. 8d shows the geometric RMS spot size across the FOV. RMS spot size is the measurement of the amount of aberration introduced by the system. The two plots correspond to the two cases of the flat sensor die (solid line) vs. curved one (broken line). As can be clearly seen from this plot, the curved sensor die enables significantly reduced blur when compared with the flat-shaped sensor die. Again, the particular values shown in this FIG. 8d plot are immaterial to the understanding of the present embodiments. This plot is included to graphically illustrate how different sensor die shapes can affect aberrations in the imaging system.

The embodiments described herein may include an array of curved sensors. For example, the embodiments described herein may include two or more of the sensors described herein, whose sensor dies may have the same characteristics such as the same pre-selected shape, size, etc. or may have one or more different characteristics, such as different pre-selected shapes and/or different sizes. In one such embodiment, the imaging system includes an additional sensor configured for detecting additional energy from the specimen and for generating output responsive to the additional detected energy. The additional sensor may be configured for detecting the additional energy and generating the output as described further herein. The energy detected by the two sensors may have one or more different characteristics such as type of energy (scattered vs. specularly reflected), wavelength, polarization, etc. For example, as described further below, different detection channels may include different sensors, and each of the sensors may be configured as described herein. However, one particularly advantageous implementation of the multiple sensor embodiment is to have multiple sensors coupled to the same collector or collection subsystem so that the multiple sensors detect energy in the same image plane, even if that image plane is curved or has some other non-flat shape.

The additional sensor includes an additional substrate and one or more additional components attached to the additional substrate. The additional sensor also includes an additional sensor die having a thinned backside and additional energy sensitive elements configured for detecting the additional energy from the specimen illuminating the thinned backside of the additional sensor die. In addition, the additional sensor includes additional discrete thermally-conductive structures formed between a frontside of the additional sensor die and the additional substrate by a flip-chip process thereby bonding the additional sensor die to the additional substrate and causing the thinned backside of the additional sensor die to have an additional pre-selected shape. At least a portion of the additional discrete thermally-conductive structures electrically connect the additional sensor die to the one or more additional components. Each of these elements of the additional sensor may be further configured as described herein.

Using more than one of the sensor embodiments described herein in a single detection channel can be particularly advantageous in some situations such as when the light from the specimen is directed to a relatively large area in the image plane and/or when the image plane has a curvature that is not easily achievable by a single sensor. In any case, the pre-selected shape and the additional pre-selected shape (the pre-selected shapes of the backsides of the sensor dies in different sensors) may be different or the same. In addition, as described further herein, in some embodiments, the imaging system is configured to independently control positions of the sensor and the additional sensor in the imaging system. The imaging system may be configured to control the position of each of the sensors in any suitable manner using any appropriate software and/or hardware known in the art of image system control.

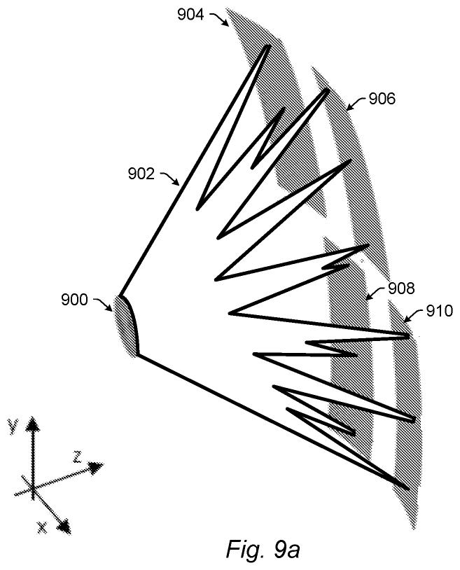

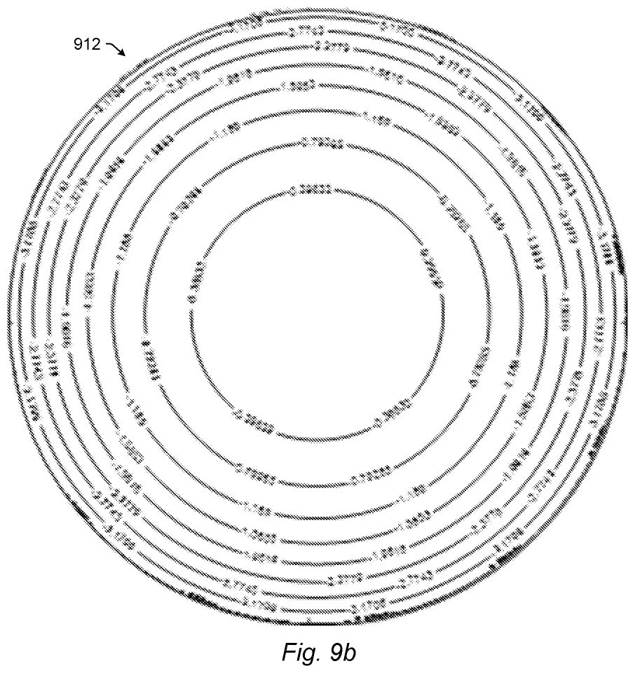

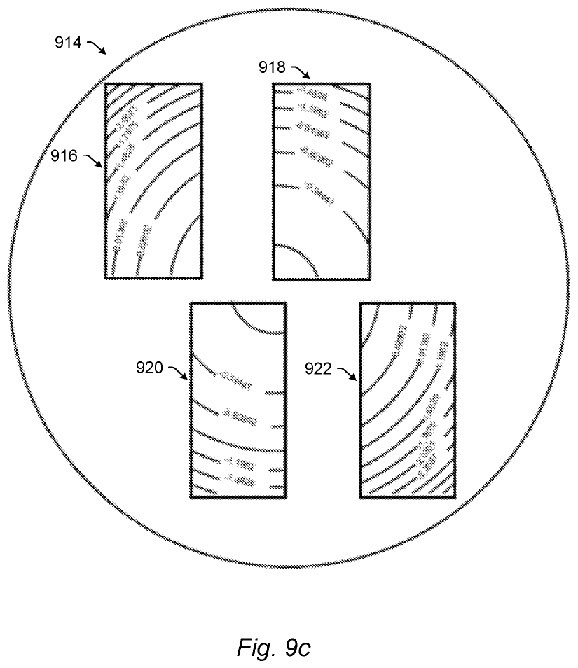

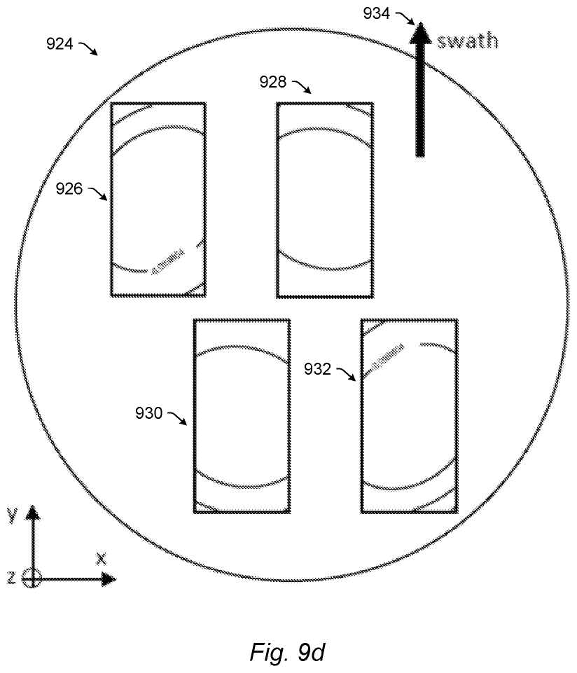

FIG. 9a illustrates one embodiment of tiling of multiple image sensors with various curvatures. In this embodiment, last optical element 900 of the imaging system (not shown in FIG. 9a) before the image plane directs light 902 to four image sensors 904, 906, 908, and 910. In this embodiment, an array of curved sensors is placed in the focal plane. Examples of possible arrangements of sensors and their application to inspection can be found in U.S. Patent Application Publication No. 2004/0175028 to Cavan published Sep. 9, 2004 and U.S. Pat. No. 9,077,862 to Brown et al. issued Jul. 7, 2015, which are incorporated by reference as if fully set forth herein. The imaging systems may be further configured as described in these references. For a system with a relatively large FOV and relatively high magnification, the image space may become substantially large and multiple sensors may be used to cover the full image. Such image space would typically have a relatively high curvature, described by a superposition of Zernike functions or by a superposition of even and odd polynomials known in the art. To obtain a substantially high-quality image, the focal plane may be curved in accordance with the field curvature.

FIG. 9a shows an example of an array of four image sensors. Those image sensors will preferably have a curvature that closely mimics the curvature of the field shown in FIG. 9b. This diagram shows contour plot 912 of the surface sag. The contour plot describes the surface shape optimized for the best optical performance. While the exact, optimal shape will vary depending on the specific imaging system design, a majority of imaging systems will produce a curvature that is similar in nature to that shown in the figure. The focal plane (or the focal surface) is imaged by an array of sensors for reasons described in the above references. FIG. 9c shows example 914 of curvatures 916, 918, 920, and 922 that image sensors 904, 906, 908, and 910, respectively, shown in FIG. 9a can have to approach the best focal surface.

The amount of surface sag shown in FIG. 9c for each individual sensor may be too large to be achieved using the assembly process described herein. Similarly, the deviation of the surface sag across each sensor represented by the density of contour lines, may be too large to be achieved using the proposed method. To address this issue, the following enhancement can be implemented. The different image sensors need not be assembled onto a common substrate, but each sensor may have its own substrate, whose position is allowed to change in all six degrees of freedom with respect to all other sensors. For example, each of sensors 904, 906, 908, and 910 shown in FIG. 9 may be formed on their own substrates. Alternatively, two or more of sensors 904, 906, 908, and 910 may be formed on a single substrate, and any sensors formed on the same substrate may be separated, e.g., by cutting the substrate, to thereby produce four separate sensors on four separate substrates. In either case, the position of each sensor along the optical axis (Z-axis) and its tilt angles in the XZ and YZ planes can be manipulated to achieve the minimum surface sag of the image sensor with respect to its substrate. FIG. 9d shows the result of such optimization. In this case, plot 924 shows curvatures 926, 928, 930, and 932 for image sensors 904, 906, 908, and 910, respectively, shown in FIG. 9a and direction 934 in which swaths are scanned on the specimen. The sparse contour lines of the surface sag in this figure (compared to FIG. 9c) indicate the substantially mild curvature and surface sag of the image sensor that can be achieved more easily using the proposed method.

While FIGS. 9a-9d show a specific configuration, the method of image sensor shape optimization is general in nature. The shape of the focal surface can always be optimized for the best imaging performance. The position along the Z-axis and the tilt angles of the individual image sensors can always be optimized to minimize the curvature and the surface sag. Such optimization will typically lead to an order of magnitude reduction of the surface sag, making it easier to utilize the assembly method outlined herein. The exact surface shape of each sensor can be consequently described by Zernike coefficients in the most general case. The surfaces will generally not be axially symmetric, since each sensor is off-axis with respect to the optical system.

It is also noted that the various numerical values in FIGS. 9b-9d are irrelevant to the understanding and full disclosure of the embodiments described herein. The numerical values are not illegible on purpose but due to the nature of the original versions of these plots and their reproducibility. Their inclusion in the present application is merely to illustrate how the multiple sensor embodiments can be configured and optimized based on the shape of the field in the image plane.

The checker-board sensor pattern shown in this embodiment is generally useful in both raster-scan and step-and-repeat inspection systems. In the former case of a raster-scan, the specimen being inspected is moving in the y-direction (referenced in FIG. 9a), and its image will move along the y-axis with respect to the image sensors. The overlap of the image sensors in the x-direction will produce image swaths of the specimen with no gaps in the inspected field along the x-direction. In a step-and-repeat inspection system, the sensor locations may be chosen such that for every two consequent inspection steps there will be no coverage gaps.

The embodiments described herein are also effective for reducing distortion-induced blur in scanning inspection systems. In some embodiments, the imaging system includes a scanning subsystem configured to scan the energy directed to the specimen by the illumination subsystem over the specimen, the illumination subsystem has a FOV on the specimen having substantially no field curvature, and the pre-selected shape of the sensor die is a curved shape. The scanning and illumination subsystems may be further configured as described herein.

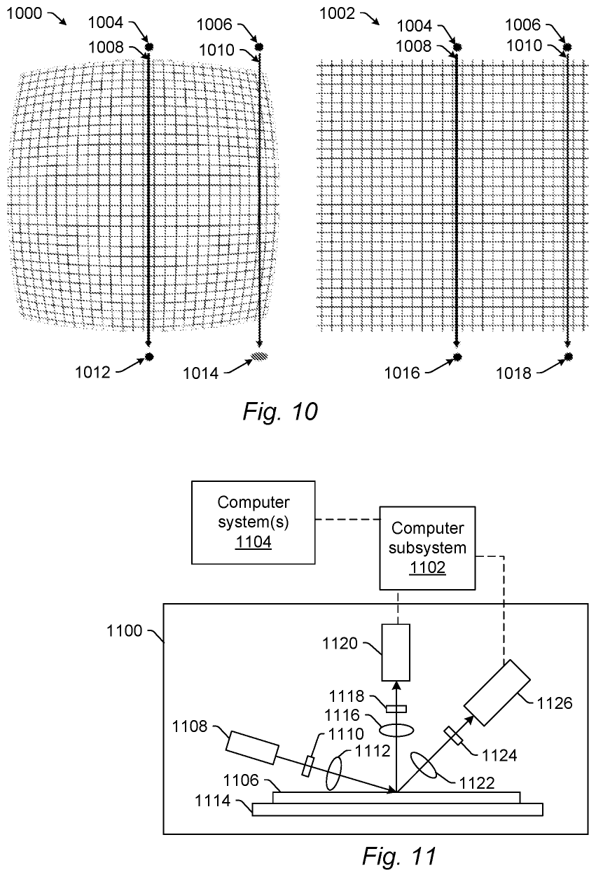

To illustrate the advantages of such an embodiment, FIG. 10 shows optical distortion and its effects on the optical resolution in a scanning system. A “perfect” grid and curved grid in the image space projected onto the object space result in distortion reversal—curved grid 1000 and perfect grid 1002, respectively. A “perfect” grid is defined herein as a grid that has substantially no curvature across the grid. In other words, a “perfect” grid as that term is used herein is defined as a grid that is substantially flat or has a negligible amount of non-flatness across it. Scanning imaging systems with relatively large FOV typically exhibit substantial field curvature as shown by curved grid 1000. Just as a perfect grid in object space corresponds to a distorted one in image space, the opposite is also true. That means that a perfect pixel array projected onto the object space, where the inspected specimen is held, will result in curved grid 1000.

Since the specimen is scanned with respect to the optics and the sensor, the defects of interest (DOI) at the edges of the field may be smeared across multiple pixels. For example, if light from defects 1004 and 1006 on a specimen (not shown in FIG. 10) is scanned across curved grid 1000 in swaths 1008 and 1010, respectively, the light from the defects is scanned across different portions of the grid that have different curvature. In particular, defect 1004 is scanned over the center of the field having little or no horizontal distortion, and defect 1006 is scanned over the edge of the field having relatively large horizontal distortion. Therefore, even if defects 1004 and 1006 have all of the same characteristics and are illuminated with light having all of the same characteristics, the output signals produced by the sensor for the defects can be different. For example, as shown in FIG. 10, image 1012 of defect 1004 is substantially different than image 1014 of defect 1006 due to smearing of the light from defect 1006 across multiple pixels at the edge of the field, which is caused by the distortion of the field.

In one such embodiment, the sensor is configured as a TDI sensor. For example, the imaging systems described herein configured for inspection will typically employ a TDI sensor, which accumulates the optical signal as the image is scanned across the pixel array. This will result in a larger effective point spread function (PSF) and therefore lower resolution and lower signal-to-noise ratio (SNR). Conversely, assembling an image sensor onto a curved surface will mimic the distortion of the system. Therefore, such a sensor projected onto the object plane will correspond to a nearly perfect grid as shown by perfect grid 1002 thereby improving the resolution and the SNR away from the center of the field. For example, as shown in FIG. 10, image 1016 of defect 1004 is substantially the same as image 1018 of defect 1006 because there is no smearing of the light from defect 1006 across multiple pixels at the edge of the field, due to the substantially perfect nature of grid 1002. Therefore, the embodiments described herein enable even more significant improvements to systems based on TDI scanning architecture.

One embodiment of an imaging system is shown in FIG. 11. Imaging system 1100 may include and/or be coupled to a computer subsystem, e.g., computer subsystem 1102 and/or one or more computer systems 1104, which may be configured as described further herein. This imaging system is based on the flip-chip sensor embodiments described herein and may be configured for different applications such as inspection or metrology.

In general, the imaging systems described herein include at least an energy source, a sensor, and a scanning subsystem. The energy source is configured for generating energy directed to a specimen by an illumination subsystem. The sensor is configured for detecting energy from the specimen and for generating output responsive to the detected energy. The scanning subsystem is configured to change a position on the specimen to which the energy is directed and from which the energy is detected. In one embodiment, as shown in FIG. 11, the energy directed to the specimen is light, and therefore the imaging system is configured as a light-based imaging system.

In the embodiment of the imaging system shown in FIG. 11, the imaging system includes an illumination subsystem configured to direct light to specimen 1106. The energy source includes at least one light source, e.g., light source 1108. The illumination subsystem is configured to direct the light to the specimen at one or more angles of incidence, which may include one or more oblique angles and/or one or more normal angles. For example, as shown in FIG. 11, light from light source 1108 is directed through optical element 1110 and then lens 1112 to specimen 1106 at an oblique angle of incidence. The oblique angle of incidence may include any suitable oblique angle of incidence, which may vary depending on, for instance, characteristics of the specimen and the process being performed on the specimen.

The illumination subsystem may be configured to direct the light to the specimen at different angles of incidence at different times. For example, the imaging system may be configured to alter one or more characteristics of one or more elements of the illumination subsystem such that the light can be directed to the specimen at an angle of incidence that is different than that shown in FIG. 11. In one such example, the imaging system may be configured to move light source 1108, optical element 1110, and lens 1112 such that the light is directed to the specimen at a different oblique angle of incidence or a normal (or near normal) angle of incidence.

In some instances, the imaging system may be configured to direct light to the specimen at more than one angle of incidence at the same time. For example, the illumination subsystem may include more than one illumination channel, one of the illumination channels may include light source 1108, optical element 1110, and lens 1112 as shown in FIG. 11 and another of the illumination channels (not shown) may include similar elements, which may be configured differently or the same, or may include at least a light source and possibly one or more other components such as those described further herein. If such light is directed to the specimen at the same time as the other light, one or more characteristics (e.g., wavelength, polarization, etc.) of the light directed to the specimen at different angles of incidence may be different such that light resulting from illumination of the specimen at the different angles of incidence can be discriminated from each other at the sensor(s).

In another instance, the imaging system may include only one light source (e.g., source 1108 shown in FIG. 11) and light from the light source may be separated into different optical paths (e.g., based on wavelength, polarization, etc.) by one or more optical elements (not shown) of the illumination subsystem. Light in each of the different optical paths may then be directed to the specimen. Multiple illumination channels may be configured to direct light to the specimen at the same time or at different times (e.g., when different illumination channels are used to sequentially illuminate the specimen). In another instance, the same illumination channel may be configured to direct light to the specimen with different characteristics at different times. For example, optical element 1110 may be configured as a spectral filter and the properties of the spectral filter can be changed in a variety of different ways (e.g., by swapping out one spectral filter with another) such that different wavelengths of light can be directed to the specimen at different times. The illumination subsystem may have any other suitable configuration known in the art for directing light having different or the same characteristics to the specimen at different or the same angles of incidence sequentially or simultaneously. The illumination subsystem may also to configured so that light enters the specimen from below (not shown in FIG. 11) and is transmitted through the specimen before being received at the sensor.

Light source 1108 may include a narrowband source such as a laser or a plasma source such as an EUV or broadband plasma (BBP) light source. In this manner, the light generated by the light source and directed to the specimen may include narrowband or broadband light. The light source may also include a laser design known in the art and configured to generate light at any suitable wavelength(s). The laser may be configured to generate light that is monochromatic or nearly monochromatic. In this manner, the laser may be a narrowband laser. The light source may also include a polychromatic light source that generates light at multiple discrete wavelengths or wavebands.

Light from optical element 1110 may be focused onto specimen 1106 by lens 1112. Although lens 1112 is shown in FIG. 11 as a single refractive optical element, in practice, lens 1112 may include a number of refractive, diffractive, and/or reflective optical elements that in combination focus the light from the optical element to the specimen. The illumination subsystem shown in FIG. 11 and described herein may include other suitable optical elements (not shown). Examples of such optical elements include, but are not limited to, polarizing component(s), spectral filter(s), spatial filter(s), reflective optical element(s), apodizer(s), beam splitter(s), aperture(s), and the like, which may include any such suitable optical elements known in the art. In addition, the imaging system may be configured to alter one or more of the elements of the illumination subsystem based on the type of illumination to be used for imaging.

The imaging system may also include a scanning subsystem configured to change the position on the specimen to which the light is directed and from which the light is detected and possibly to cause the light to be scanned over the specimen. For example, the imaging system may include stage 1114 on which specimen 1106 is disposed during imaging. The scanning subsystem may include any suitable mechanical and/or robotic assembly (that includes stage 1114) that can be configured to move the specimen such that the light can be directed to and detected from different positions on the specimen. In addition, or alternatively, the imaging system may be configured such that one or more optical elements of the imaging system perform some scanning of the light over the specimen such that the light can be directed to and detected from different positions on the specimen. In instances in which the light is scanned over the specimen, the light may be scanned over the specimen in any suitable fashion such as in a serpentine-like path or in a spiral path.

The imaging system further includes one or more detection channels. At least one of the detection channel(s) includes a sensor configured to detect light from the specimen due to illumination of the specimen by the imaging system and to generate output responsive to the detected light. For example, the imaging system shown in FIG. 11 includes two detection channels, one formed by collector 1116, element 1118, and sensor 1120 and another formed by collector 1122, element 1124, and sensor 1126. As shown in FIG. 11, the two detection channels are configured to collect and detect light at different angles of collection. In some instances, both detection channels are configured to detect scattered light, and the detection channels are configured to detect light that is scattered at different angles from the specimen. However, one or more of the detection channels may be configured to detect another type of light from the specimen (e.g., reflected light).

As further shown in FIG. 11, both detection channels are shown positioned in the plane of the paper and the illumination subsystem is also shown positioned in the plane of the paper. Therefore, in this embodiment, both detection channels are positioned in (e.g., centered in) the plane of incidence. However, one or more of the detection channels may be positioned out of the plane of incidence. For example, the detection channel formed by collector 1122, element 1124, and sensor 1126 may be configured to collect and detect light that is scattered out of the plane of incidence. Therefore, such a detection channel may be commonly referred to as a “side” channel, and such a side channel may be centered in a plane that is substantially perpendicular to the plane of incidence.

Although FIG. 11 shows an embodiment of the imaging system that includes two detection channels, the imaging system may include a different number of detection channels (e.g., only one detection channel or two or more detection channels). In one such instance, the detection channel formed by collector 1122, element 1124, and sensor 1126 may form one side channel as described above, and the imaging system may include an additional detection channel (not shown) formed as another side channel that is positioned on the opposite side of the plane of incidence. Therefore, the imaging system may include the detection channel that includes collector 1116, element 1118, and sensor 1120 and that is centered in the plane of incidence and configured to collect and detect light at scattering angle(s) that are at or close to normal to the specimen surface. This detection channel may therefore be commonly referred to as a “top” channel, and the imaging system may also include two or more side channels configured as described above. As such, the imaging system may include at least three channels (i.e., one top channel and two side channels), and each of the at least three channels has its own collector, each of which is configured to collect light at different scattering angles than each of the other collectors.

As described further above, each of the detection channels included in the imaging system may be configured to detect scattered light. Therefore, the imaging system shown in FIG. 11 may be configured for dark field (DF) imaging of specimens. However, the imaging system may also or alternatively include detection channel(s) that are configured for bright field (BF) imaging of specimens. In other words, the imaging system may include at least one detection channel that is configured to detect light specularly reflected from the specimen. Therefore, the imaging systems described herein may be configured for only DF, only BF, or both DF and BF imaging. Although each of the collectors are shown in FIG. 11 as single refractive optical elements, each of the collectors may include one or more refractive optical elements and/or one or more reflective optical elements. The collectors shown in FIG. 11 may also be configured as or replaced with the camera lens subsystem or tube lens subsystem embodiments described herein.

The sensors included in the one or more detection channels may be configured according to any of the embodiments described herein. The output that is generated by each of the sensors included in each of the detection channels of the imaging system may be image signals or image data or any other suitable output known in the art. In addition, although each of the detection channels is shown in FIG. 11 as including a single sensor, each of the detection channels may include multiple sensors configured as shown in FIG. 9a and described further herein. Furthermore, different detection channels included in the imaging system may include different sensor embodiments described herein. For example, sensor 1120 may be configured to have a different pre-selected shape than sensor 1126.

It is noted that FIG. 11 is provided herein to generally illustrate one embodiment of a configuration of an imaging system that may include one or more of the sensor embodiments described herein. Obviously, the imaging system configuration described herein may be altered to optimize the performance of the imaging system as is normally performed when designing a commercial imaging system. In addition, the imaging systems described herein may be implemented using an existing system (e.g., by adding functionality described herein to an existing inspection system) such as the 29xx/39xx series of tools that are commercially available from KLA Corp., Milpitas, Calif. For some such imaging systems, the sensors described herein may be provided as optional elements of the imaging system (e.g., in addition to other pre-existing sensors of the imaging system). Alternatively, the imaging system described herein may be designed “from scratch” to provide a completely new imaging system.

Computer subsystem 1102 may be coupled to the sensors of the imaging system in any suitable manner (e.g., via one or more transmission media, which may include “wired” and/or “wireless” transmission media) such that the computer subsystem can receive the output generated by the sensors. Computer subsystem 1102 may be configured to perform a number of functions with or without the output of the sensors including the steps and functions described further herein. As such, the steps described herein may be performed “on-tool,” by a computer subsystem that is coupled to or part of an imaging system. In addition, or alternatively, computer system(s) 1104 may perform one or more of the steps described herein. Therefore, one or more of the steps described herein may be performed “off-tool,” by a computer system that is not directly coupled to an imaging system. Computer subsystem 1102 and computer system(s) 1104 may be further configured as described herein.

Computer subsystem 1102 (as well as other computer subsystems described herein) may also be referred to herein as computer system(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high-speed processing and software, either as a standalone or a networked tool.

If the system includes more than one computer subsystem, then the different computer subsystems may be coupled to each other such that images, data, information, instructions, etc. can be sent between the computer subsystems. For example, computer subsystem 1102 may be coupled to computer system(s) 1104 as shown by the dashed line in FIG. 11 by any suitable transmission media, which may include any suitable wired and/or wireless transmission media known in the art. Two or more of such computer subsystems may also be effectively coupled by a shared computer-readable storage medium (not shown).

Although the imaging system is described above as including an optical or light-based energy source, in another embodiment, the energy source is configured as an electron beam source. In such an imaging system, the energy directed to the specimen includes electrons, and the energy detected from the specimen includes electrons. In one such embodiment shown in FIG. 11a, the imaging system includes electron column 1128, which may be coupled to computer subsystem 1130. Computer subsystem 1130 may be configured as described above. In addition, such an imaging system may be coupled to another one or more computer systems in the same manner described above and shown in FIG. 11.

As also shown in FIG. 11a, the electron column includes electron beam source 1132 configured to generate electrons that are focused to specimen 1134 by one or more elements 1136. The electron beam source may include, for example, a cathode source or emitter tip, and one or more elements 1136 may include, for example, a gun lens, an anode, a beam limiting aperture, a gate valve, a beam current selection aperture, an electrostatic or magnetic type objective lens suited for charged particle imaging, and a scanning subsystem, all of which may include any such elements known in the art.

Electrons returned from the specimen may be focused by one or more elements 1138 to sensor 1140. One or more elements 1138 may include, for example, a camera lens subsystem or a tube lens subsystem, which may be configured as described herein. Sensor 1140 may be configured according to any of the embodiments described herein. In addition, sensor 1140 may be replaced with a sensor array such as that shown in FIG. 9a and described further above.

The electron column may include any other suitable elements known in the art. In addition, the electron column may be further configured as described in U.S. Pat. No. 8,664,594 issued Apr. 4, 2014 to Jiang et al., U.S. Pat. No. 8,692,204 issued Apr. 8, 2014 to Kojima et al., U.S. Pat. No. 8,698,093 issued Apr. 15, 2014 to Gubbens et al., and U.S. Pat. No. 8,716,662 issued May 6, 2014 to MacDonald et al., which are incorporated by reference as if fully set forth herein.

Although the electron column is shown in FIG. 11a as being configured such that the electrons are directed to the specimen at an oblique angle of incidence and are scattered from the specimen at another oblique angle, the electron beam may be directed to and scattered from the specimen at any suitable angles. In addition, the imaging system may be configured to use multiple modes to generate output for the specimen as described further herein (e.g., with different illumination angles, collection angles, etc.). The multiple modes of the imaging system may be different in any output generation parameters of the imaging system.

Computer subsystem 1130 may be coupled to sensor 1140 as described above. The sensor may detect electrons returned from the surface of the specimen thereby forming images of (or other output for) the specimen. Computer subsystem 1130 may be configured to perform one or more functions on output generated by sensor 1140, which may be performed as described further herein. Computer subsystem 1130 may be configured to perform any additional step(s) described herein. A system that includes the imaging system shown in FIG. 11a may be further configured as described herein.

It is noted that FIG. 11a is provided herein to generally illustrate another embodiment of a configuration of an imaging system that may include one or more of the sensor embodiments described herein. As with the imaging system shown in FIG. 11, the imaging system configuration shown in FIG. 11a may be altered to optimize the performance of the imaging system as is normally performed when designing a commercial system. In addition, the imaging systems described herein may be implemented using an existing system (e.g., by adding sensors described herein to an existing system) such as tools that are commercially available from KLA. For some such systems, the sensors described herein may be provided as optional elements of the system (e.g., in addition to existing sensors of the system). Alternatively, the imaging system described herein may be designed “from scratch” to provide a completely new imaging system.

Although the imaging system is described above as including a light or electron beam energy source, the imaging subsystem may include an ion beam energy source. Such an imaging system may be configured as shown in FIG. 11a except that the electron beam source may be replaced with any suitable ion beam source known in the art. In addition, the imaging system may include any other suitable ion beam imaging system such as those included in commercially available focused ion beam (FIB) systems, helium ion microscopy (HIM) systems, and secondary ion mass spectroscopy (SIMS) systems.

As further noted above, the imaging system may be configured to have multiple modes. In general, a “mode” is defined by the values of parameters of the imaging system used to generate output for the specimen. Therefore, modes that are different may be different in the values for at least one of the imaging parameters of the imaging system (other than position on the specimen at which the output is generated). For example, for a light-based imaging system, different modes may use different wavelengths of light. The modes may be different in the wavelengths of light directed to the specimen as described further herein (e.g., by using different light sources, different spectral filters, etc. for different modes). In another embodiment, different modes may use different illumination channels. For example, as noted above, the imaging system may include more than one illumination channel. As such, different illumination channels may be used for different modes.

The multiple modes may also be different in illumination and/or collection/detection. For example, as described further above, the imaging system may include multiple sensors. Therefore, one of the sensors may be used for one mode and another of the sensors may be used for another mode. Furthermore, the modes may be different from each other in more than one way described herein (e.g., different modes may have one or more different illumination parameters and one or more different detection parameters). In addition, the multiple modes may be different in perspective, meaning having either or both of different angles of incidence and angles of collection, which are achievable as described further above. The imaging system may be configured to scan the specimen with the different modes in the same scan or different scans, e.g., depending on the capability of using multiple modes to scan the specimen at the same time.

In some instances, the imaging systems described herein may be configured as inspection systems. However, the imaging systems described herein may be configured as another type of semiconductor-related quality control type system such as a defect review system and a metrology system. For example, the embodiments of the imaging systems described herein and shown in FIGS. 11 and 11a may be modified in one or more parameters to provide different imaging capability depending on the application for which they will be used. In one such example, the imaging system shown in FIG. 11 may be configured to have a higher resolution if it is to be used for defect review or metrology rather than for inspection. In other words, the embodiments of the imaging system shown in FIGS. 11 and 11a describe some general and various configurations for an imaging system that can be tailored in a number of manners that will be obvious to one skilled in the art to produce imaging systems having different imaging capabilities that are more or less suitable for different applications.

As noted above, the imaging system is configured for directing energy (e.g., light, electrons) to and/or scanning energy over a physical version of the specimen thereby generating actual images for the physical version of the specimen. In this manner, the imaging system may be configured as an “actual” imaging system, rather than a “virtual” system. However, a storage medium (not shown) and computer system(s) 1104 shown in FIG. 11 may be configured as a “virtual” system. In particular, the storage medium and the computer system(s) are not part of imaging system 1100 and do not have any capability for handling the physical version of the specimen but may be configured as a virtual inspector that performs inspection-like functions, a virtual metrology system that performs metrology-like functions, a virtual defect review tool that performs defect review-like functions, etc. using stored sensor output. Systems and methods configured as “virtual” systems are described in commonly assigned U.S. Pat. No. 8,126,255 issued on Feb. 28, 2012 to Bhaskar et al., U.S. Pat. No. 9,222,895 issued on Dec. 29, 2015 to Duffy et al., and 9,816,939 issued on Nov. 14, 2017 to Duffy et al., which are incorporated by reference as if fully set forth herein. The embodiments described herein may be further configured as described in these patents. For example, a computer subsystem described herein may be further configured as described in these patents.

In one embodiment, the imaging system includes a computer subsystem configured to determine information for the specimen based on the output generated by the sensor. For example, the imaging system shown in FIG. 11 may include computer subsystem 1102 and/or computer system(s) 1104, and the imaging system shown in FIG. 11a may include computer subsystem 1130. These computer subsystems or systems may be coupled to one or more sensors of the imaging system as described above so that the computer subsystems or systems receive the output generated by the sensor(s). The information determined and the manner in which the output generated by the sensor or multiple sensors is used for information determination may vary depending on the process being performed on the specimen. The determining information step may be performed by the computer subsystem using an algorithm or method such as one of those described further herein or any other suitable algorithm or method known in the art.

In another embodiment, the imaging system includes a computer subsystem configured to detect defects on the specimen based on the output generated by the sensor. In general, the output generated by the sensor may be used for defect detection in the same manner as any other images. In other words, the output generated by the sensors described herein is not defect detection algorithm or method specific, and detecting the defects using the output may be performed using any suitable defect detection algorithm or method known in the art. For example, defect detection may be performed by subtracting a reference from the output to thereby generate a difference image and applying a threshold to the difference image. Any pixels in the difference image having a value above the threshold may be identified as a defect, and all other pixels may not be identified as a defect. Of course, this is possibly the most simple way in which defect detection can be performed and is included herein as merely a non-limiting example.

In some embodiments, therefore, detecting defects on the specimen may include generating or determining information for the specimen, which may include information for any defects detected on the specimen. In such instances, the information may include, for example, a type of defect detected, a position of a detected defect with respect to one or more of the specimen image, the specimen, the imaging system, and a design for the specimen, and any other information generated for the defect by the defect detection method or algorithm and/or the computer subsystem. The information determined by the computer subsystem may also or alternatively include any suitable defect attributes, e.g., classification, size, shape, etc., (other than reported defect location) that can be determined from the output described herein and/or its alignment to other information for the specimen such as design data. Such information may be output and/or stored by the computer subsystem as described further herein.

Unlike inspection processes, a defect review process generally revisits discrete locations on a specimen at which a defect has been detected. An imaging system configured for defect review may generate specimen images as described herein, which may be input to the computer subsystem as described herein for one or more defect review functions such as defect re-detection, defect attribute determination, defect classification, and defect root cause determination. For defect review applications, the computer subsystem may also be configured for using any suitable defect review method or algorithm used on any suitable defect review tool to determine information for the defect or the specimen from the sensor output, possibly in combination with any other information determined by the defect review process or from the sensor output.

In some embodiments, the imaging system may be configured for metrology of the specimen. In one such embodiment, the information includes a measurement of one or more structures formed on the specimen. For example, the imaging systems described herein may be configured as metrology tools, and the sensor output generated by such a metrology tool can be used to determine metrology information for the specimen. The metrology information may include any metrology information of interest, which may vary depending on the structures on the specimen. Examples of such metrology information include, but are not limited to, critical dimensions (CDs) such as line width and other dimensions of the specimen structures. For metrology applications, the computer subsystem may also be configured for using any suitable metrology method or algorithm used on any suitable metrology tool to determine information for the specimen from the sensor output, possibly in combination with any other information determined by the metrology process or from the sensor output.

The computer subsystem may also be configured for generating results that include the determined information, which may include any of the results or information described herein. The results of determining the information may be generated by the computer subsystem in any suitable manner. All of the embodiments described herein may be configured for storing results of one or more steps of the embodiments in a computer-readable storage medium. The results may include any of the results described herein and may be stored in any manner known in the art. The results that include the determined information may have any suitable form or format such as a standard file type. The storage medium may include any storage medium described herein or any other suitable storage medium known in the art.

After the results have been stored, the results can be accessed in the storage medium and used by any of the method or system embodiments described herein, formatted for display to a user, used by another software module, method, or system, etc. to perform one or more functions for the specimen or another specimen of the same type. For example, results produced by the computer subsystem may include information for any defects detected on the specimen such as location, etc., of the bounding boxes of the detected defects, detection scores, information about defect classifications such as class labels or IDs, any defect attributes determined from any of the images, etc., predicted specimen structure measurements, dimensions, shapes, etc. or any such suitable information known in the art. That information may be used by the computer subsystem or another system or method for performing additional functions for the specimen and/or the detected defects such as sampling the defects for defect review or other analysis, determining a root cause of the defects, etc.

Such functions also include, but are not limited to, altering a process such as a fabrication process or step that was or will be performed on the specimen in a feedback or feedforward manner, etc. For example, the computer subsystem may be configured to determine one or more changes to a process that was performed on the specimen and/or a process that will be performed on the specimen based on the determined information. The changes to the process may include any suitable changes to one or more parameters of the process. In one such example, the computer subsystem preferably determines those changes such that the defects can be reduced or prevented on other specimens on which the revised process is performed, the defects can be corrected or eliminated on the specimen in another process performed on the specimen, the defects can be compensated for in another process performed on the specimen, etc. The computer subsystem may determine such changes in any suitable manner known in the art.

Those changes can then be sent to a semiconductor fabrication system (not shown) or a storage medium (not shown) accessible to both the computer subsystem and the semiconductor fabrication system. The semiconductor fabrication system may or may not be part of the system embodiments described herein. For example, the imaging subsystem and/or the computer subsystem described herein may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a chemical-mechanical polishing (CMP) tool, a deposition tool, and the like.

Each of the embodiments of each of the systems described above may be combined together into one single embodiment.

An additional embodiment relates to a non-transitory computer-readable medium storing program instructions executable on a computer system for performing a computer-implemented method for determining information for a specimen. One such embodiment is shown in FIG. 12. In particular, as shown in FIG. 12, non-transitory computer-readable medium 1200 includes program instructions 1202 executable on computer system(s) 1204. The computer-implemented method may include any step(s) of any method(s) described herein.

Program instructions 1202 for the algorithms implementing methods such as those described herein may be stored on computer-readable medium 1200. The computer-readable medium may be a storage medium such as a magnetic or solid-state disk, a magnetic tape, or any other suitable non-transitory computer-readable medium known in the art.

The algorithms may be implemented in any of various ways, including procedure-based techniques, component-based techniques, object-oriented techniques, implementation of neural network architectures, among others. For example, the program instructions may be implemented using suitable programming frameworks and languages known in the art such as C, C++, or Python, and executed on local, remote, or centrally managed computation systems, or a combination of these systems. Custom accelerators may be implemented in application-specific integrated circuit devices (ASIC chips), in field-programmable gate arrays (FPGAs) with custom configurations, or in graphics processing units (GPUs), separately or in combination as desired.

Computer system(s) 1204 may be configured according to any of the embodiments described herein.

Further modifications and alternative embodiments of various aspects of the invention will be apparent to those skilled in the art in view of this description. For example, sensors, imaging systems, and methods for forming a sensor are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A sensor, comprising:
a substrate;
one or more components attached to the substrate;
a sensor die having a thinned backside and energy sensitive elements configured for detecting energy illuminating the thinned backside of the sensor die; and
discrete thermally-conductive structures formed between a frontside of the sensor die and the substrate by a flip-chip process thereby bonding the sensor die to the substrate and causing the thinned backside of the sensor die to have a pre-selected shape, wherein at least a portion of the discrete thermally-conductive structures electrically connect the sensor die to the one or more components.

2. The sensor of claim 1, wherein prior to bonding the sensor die to the substrate in the flip-chip process, the discrete thermally-conductive structures are formed on the substrate and a shape of one or more of the discrete thermally-conductive structures is modified so that the discrete thermally-conductive structures in combination have a shape that is substantially the same as the pre-selected shape.

3. The sensor of claim 1, wherein the pre-selected shape is determined prior to the flip-chip process, and wherein a shape of one or more of the discrete thermally-conductive structures formed on the substrate prior to bonding the sensor die to the substrate in the flip-chip process is altered based on the pre-selected shape.

4. The sensor of claim 1, wherein a surface of the substrate on which the discrete thermally-conductive structures are formed has a shape different than the pre-selected shape.

5. The sensor of claim 1, wherein a surface of the substrate on which the discrete thermally-conductive structures are formed has a shape determined based on the pre-selected shape.

6. The sensor of claim 1, wherein the pre-selected shape is a curved shape.

7. The sensor of claim 1, wherein the pre-selected shape is defined by a higher order polynomial.

8. The sensor of claim 1, wherein the substrate is formed of a ceramic material.

9. The sensor of claim 1, wherein the substrate is formed of a material selected based on a coefficient of thermal expansion for the material determined from a size of the sensor die and the pre-selected shape.

10. The sensor of claim 1, wherein the discrete thermally-conductive structures are formed of a material selected based on a reflow temperature for the material determined from a size of the sensor die and the pre-selected shape.

11. The sensor of claim 1, further comprising an underfill material formed around the discrete thermally-conductive structures and between the frontside of the sensor die and the substrate.

12. The sensor of claim 11, wherein the underfill material is configured to stabilize the sensor die when the sensor die is subject to a vacuum.

13. The sensor of claim 11, wherein the underfill material comprises a resin containing dispersed particles formed of a dielectric material with high thermal conductivity.

14. The sensor of claim 1, further comprising thermally and electrically conductive vias formed in the substrate with at least a subset configured for connecting the at least the portion of the discrete thermally-conductive structures to the one or more components thereby connecting the sensor die to the one or more components.

15. The sensor of claim 1, wherein the one or more components are configured for performing one or more functions on output generated by the energy sensitive elements responsive to the detected energy.

16. The sensor of claim 1, wherein the energy sensitive elements are further configured for detecting deep ultraviolet light.

17. The sensor of claim 1, wherein the energy sensitive elements are further configured for detecting vacuum ultraviolet light.

18. The sensor of claim 1, wherein the energy sensitive elements are further configured for detecting extreme ultraviolet light.

19. The sensor of claim 1, wherein the energy sensitive elements are further configured for detecting x-rays.

20. An imaging system, comprising:
an energy source configured for generating energy directed to a specimen by an illumination subsystem; and
a sensor configured for detecting energy from the specimen and for generating output responsive to the detected energy; wherein the sensor comprises:
a substrate;
one or more components attached to the substrate;
a sensor die having a thinned backside and energy sensitive elements configured for detecting the energy from the specimen illuminating the thinned backside of the sensor die; and
discrete thermally-conductive structures formed between a frontside of the sensor die and the substrate by a flip-chip process thereby bonding the sensor die to the substrate and causing the thinned backside of the sensor die to have a pre-selected shape, wherein at least a portion of the discrete thermally-conductive structures electrically connect the sensor die to the one or more components.

21. The system of claim 20, further comprising a computer subsystem configured to detect defects on the specimen based on the output generated by the sensor.

22. The system of claim 20, further comprising a computer subsystem configured to determine information for the specimen based on the output generated by the sensor.

23. The system of claim 22, wherein the information comprises a measurement of one or more structures formed on the specimen.

24. The system of claim 20, further comprising a camera lens subsystem configured to direct the energy from the specimen to the sensor.

25. The system of claim 20, further comprising a tube lens subsystem configured to direct the energy from the specimen to the sensor.

26. The system of claim 20, further comprising an additional sensor configured for detecting additional energy from the specimen and for generating output responsive to the additional detected energy; wherein the additional sensor comprises:
an additional substrate;
one or more additional components attached to the additional substrate;
an additional sensor die having a thinned backside and additional energy sensitive elements configured for detecting the additional energy from the specimen illuminating the thinned backside of the additional sensor die; and
additional discrete thermally-conductive structures formed between a frontside of the additional sensor die and the additional substrate by a flip-chip process thereby bonding the additional sensor die to the additional substrate and causing the thinned backside of the additional sensor die to have an additional pre-selected shape, wherein at least a portion of the additional discrete thermally-conductive structures electrically connect the additional sensor die to the one or more additional components.

27. The system of claim 26, wherein the pre-selected shape and the additional pre-selected shape are different.

28. The system of claim 26, wherein the pre-selected shape and the additional pre-selected shape are the same.

29. The system of claim 26, wherein the imaging system is configured to independently control positions of the sensor and the additional sensor in the imaging system.

30. The system of claim 20, further comprising a scanning subsystem configured to scan the energy directed to the specimen by the illumination subsystem over the specimen, wherein the illumination subsystem has a field of view on the specimen having substantially no field curvature, and wherein the pre-selected shape is a curved shape.

31. The system of claim 30, wherein the sensor is further configured as a time delay integration sensor.

32. A method for forming a sensor, comprising:
forming discrete thermally-conductive structures on a substrate;
altering a shape of the discrete thermally-conductive structures based on a pre-selected shape of a thinned backside of a sensor die; and
bonding a frontside of the sensor die to the substrate via the discrete thermally-conductive structures thereby causing the thinned backside of the sensor die to have the pre-selected shape, wherein at least a portion of the discrete thermally-conductive structures electrically connect the sensor die to one or more components attached to the substrate; and
wherein the sensor die has energy sensitive elements configured for detecting energy illuminating the thinned backside of the sensor die.
